(19) United States
(12) Patent Application Publication
(10) Pub. No.: US 2025/0229363 A1
(43) Pub. Date: Jul. 17, 2025

(54) LASER ADJUSTMENT METHOD AND LASER MACHINING DEVICE

(71) Applicants: NICHIA CORPORATION, Anan-shi, Tokushima (JP); HAMAMATSU PHOTONICS K.K., Hamamatsu-shi, Shizuoka (JP)

(72) Inventors: Ryota SUGIO, Hamamatsu-shi, Shizuoka (JP); Yusuke SEKIMOTO, Hamamatsu-shi, Shizuoka (JP); Minoru YAMAMOTO, Anan-shi, Tokushima (JP); Naoto INOUE, Anan-shi, Tokushima (JP); Taichi OKUBO, Anan-shi, Tokushima (JP); Hiroaki TAMEMOTO, Anan-shi, Tokushima (JP)

(73) Assignees: NICHIA CORPORATION, Anan-shi, Tokushima (JP); HAMAMATSU PHOTONICS K.K., Hamamatsu-shi, Shizuoka (JP)

(21) Appl. No.: 18/703,761

(22) PCT Filed: Oct. 21, 2022
(86) PCT No.: PCT/JP2022/039376

§ 371 Date: Apr. 23, 2024

(30) Foreign Application Priority Data
Oct. 29, 2021 (JP) 2021-177743

(51) Int. Cl. B23K 26/36; H01L 21/67

(52) U.S. Cl. CPC B23K 26/36; H01L 21/67092

(57) ABSTRACT

Provided is a laser adjustment method including: a first preparation process of acquiring an image including an image of a first damage formed in a first film due to irradiation of a first film wafer including a first wafer and the first film provided in the first wafer with first laser light as a first damage image; a second preparation process of preparing a second film wafer including a second wafer and a second film provided in the second wafer; a processing process of irradiating the second film wafer with second laser light after the first preparation process and the second preparation process to form a second damage in the second film; an imaging process of imaging the second film to acquire an image including an image of the second damage as a second damage image after the processing process; and an adjustment process of adjusting an aberration.

### TECHNICAL FIELD

The present disclosure relates to a laser adjustment method and a laser processing apparatus.

### BACKGROUND ART

Patent Literature 1 discloses a laser dicing device. The laser dicing device includes a stage that moves a wafer, a laser head that irradiates the wafer with laser light, and a control unit that controls each unit. The laser head has a laser light source that emits processing laser light for forming a modified region inside the wafer, a dichroic mirror and a converging lens that are sequentially arranged on an optical path of the processing laser light, and an AF device.

### CITATION LIST

### Patent Literature

Patent Literature 1: Japanese Patent No. 5743123

### SUMMARY OF INVENTION

### Technical Problem

By the way, in a case of forming the modified region inside the wafer by irradiating the wafer with the laser light, in the laser light emitted to a processing object, light that is not reflected from an incident surface, is not absorbed in the processing object, and does not contribute to modification of the processing object may reach a surface opposite to the incident surface of the processing object (so-called leaked light may occur). There is a concern that the leaked light may be the cause for a damage of a device or the like that is formed on the surface of the wafer which is opposite to the laser light incident surface in the wafer. In a case where a plurality of devices exist, the damage caused by the leaked light varies for every device, and thus a variance may occur in processing results.

An object of the present disclosure is to provide a laser adjustment method and a laser processing apparatus capable of suppressing a variation in processing results.

### Solution to Problem

A laser adjustment method according to the present disclosure includes: a first preparation process of acquiring an image including an image of a first damage formed in a first film due to irradiation of a first film wafer including a first wafer and the first film provided in the first wafer with first laser light as a first damage image; a second preparation process of preparing a second film wafer including a second wafer and a second film provided in the second wafer; a processing process of irradiating the second film wafer with second laser light after the first preparation process and the second preparation process to form a second damage in the second film; an imaging process of imaging the second film to acquire an image including an image of the second damage as a second damage image after the processing process; and an adjustment process of adjusting an aberration that is applied to the second laser light so that the image of the second damage included in the second damage image becomes close to the image of the first damage included in the first damage image after the imaging process.

A laser processing apparatus according to the present disclosure includes: a support unit configured to support an object; a laser irradiation unit configured to irradiate the object supported by the support unit with laser light; an imaging unit configured to image the object; a retention unit configured to retain an image; and a control unit configured to control at least the laser irradiation unit and the imaging unit. The laser irradiation unit includes a spatial light modulator configured to modulate the laser light in correspondence with a modulation pattern and emit the laser light, the retention unit retains an image including an image of a first damage formed in a first film due to irradiation of a first film wafer including a first wafer and the first film provided in the first wafer with first laser light as a first damage image, and the control unit executes a processing process of irradiating a second film wafer with second laser light according to control by the laser irradiation unit in a state in which as the object, the second film wafer including a second wafer and the second film provided in the second wafer is supported by the support unit, an imaging process of imaging the second film according to control by the imaging unit after the processing process to acquire an image including an image of a second damage formed in the second film due to irradiation with the second laser light as a second damage image, and an adjustment process of adjusting an aberration that is applied to the second laser light by adjusting the modulation pattern so that the image of the second damage included in the second damage image becomes close to the image of the first damage included in the first damage image.

In the method and the apparatus, the image including the image of the first damage formed in the first film of the first film wafer that is a reference of adjustment is prepared as the first damage image. On the other hand, the second film wafer is irradiated with the second laser light to form a second damage and the second film is imaged to acquire the second damage image including the image of the second damage. Then, the aberration that is applied to the second laser light is adjusted so that the image of the second damage included in the second damage image becomes close to the image of the first damage included in the first damage image. According to this, the damage shown in the second film of the second film wafer can be close to the damage shown in the first film of the first film wafer. As a result, even in a case where a plurality of apparatuses exist, when the same adjustment is executed over the plurality of apparatuses with the first damage image set as a reference, a variation in processing results between the plurality of apparatuses (machine difference) is suppressed. Note that, as described above, when using the film wafer in which a film is formed on one surface of the wafer, a damage that may be generated in a device due to leaked light of the laser light during processing of an actual wafer is visualized, and can be used for adjustment of the laser light.

The laser adjustment method according to the present disclosure may further include a display process of displaying the first damage image and the second damage image after the imaging process. In the adjustment process, after the display process, the aberration that is applied to the second laser light may be adjusted so that the image of the second damage becomes close to the image of the first damage on the basis of a comparison result between the image of the second damage included in the second damage image and the image of the first damage included in the first damage image. In this way, when performing display and comparison of images, the aberration can be easily and reliably adjusted so that the second damage becomes close to the first damage.

In the laser adjustment method according to the present disclosure, in the adjustment process, a comma aberration that is applied to the second laser light may be adjusted. In this way, when suppressing a variation in processing results, the comma aberration that is applied to the laser light may be adjusted.

in the laser adjustment method according to the present disclosure, in the first preparation process, the first wafer may be irradiated with the first laser light from a surface side of the first wafer which is opposite to the first film to further acquire an image including an image of a first processing mark formed in the first wafer as a first processing image, the first damage image may include an image of the first damage formed by leaked light of the first laser light when forming the first processing mark included in the first processing image, in the processing process, the second wafer may be irradiated with the second laser light from a surface side of the second wafer which is opposite to the second film to form a second processing mark in the second wafer and form the second damage in the second film by leaked light of the second laser light, in the imaging process, the second wafer may be imaged to acquire an image including an image of the second processing mark as a second processing image, and in the adjustment process, the comma aberration that is applied to the second laser light may be adjusted so that the amount and a direction of a deviation between a position of the image of the second processing mark included in the second processing image and a central position of the image of the second damage included in the second damage image become close to the amount and a direction of a deviation between a position of the image of the first processing mark included in the first processing image and a central position of the image of the first damage included in the first damage image. In this case, the amount of and the direction of the deviation between the processing mark shown in the second wafer and the damage shown in the second film can become close to the first film wafer as a reference. As a result, a variation in processing results can be reliably suppressed.

In the laser adjustment method according to the present disclosure, in the adjustment process, an astigmatism that is applied to the second laser light may be adjusted. In this way, when suppressing a variation in processing results, the astigmatism that is applied to the laser light may be adjusted.

In the laser adjustment method according to the present disclosure, in the first preparation process, a first angle that is an angle of the image of the first damage included in the first damage image with respect to a reference direction, and a first ellipticity that is an ellipticity of the image of the first damage may be further acquired, and in the adjustment process, the astigmatism that is applied to the second laser light may be adjusted so that a second angle that is an angle of the image of the second damage included in the second damage image with respect to the reference direction and a second ellipticity that is an ellipticity of the image of the second damage become close to the first angle and the first ellipticity. In this case, the angle and the ellipticity with respect to the reference direction of the damage shown in the second film become close to those of the first film that is a reference. As a result, a variation in processing results can be reliably suppressed.

In the laser adjustment method according to the present disclosure, in the adjustment process, a spherical aberration that is applied to the second laser light may be adjusted. In this way, when suppressing a variation in processing results, the spherical aberration that is applied to the laser light may be adjusted.

In the laser adjustment method according to the present disclosure, in the processing process, the second film may be irradiated with the second laser light a plurality of times while varying the spherical aberration that is applied to the second laser light to form a plurality of the second damages in the second film, in the imaging process, the second film may be imaged to acquire the second damage image including images of a plurality of the second damages, and in the adjustment process, the aberration that is applied to the second laser light may be adjusted so that the spherical aberration when forming a second damage, which is relatively close to the image of the first damage included in the first damage image, among the images of the plurality of second damages included in the second damage image is applied to the second laser light. In this case, the aberration can be adjusted so that the damage shown in the second film of the second film wafer more reliably becomes close to the damage shown in the first film of the first film wafer.

In the laser adjustment method according to the present disclosure, in the adjustment process, a trefoil aberration that is applied to the second laser light may be adjusted. In this way, when suppressing a variation in processing results, the trefoil aberration that is applied to the laser light may be adjusted.

In the laser adjustment method according to the present disclosure, in the processing process, the second film may be irradiated with the second laser light a plurality of times while varying the trefoil aberration that is applied to the second laser light to form a plurality of the second damages in the second film, in the imaging process, the second film may be imaged to acquire the second damage image including images of the plurality of second damages, and in the adjustment process, the aberration that is applied to the second laser light may be adjusted so that the trefoil aberration when forming a second damage, which is relatively close to the image of the first damage included in the first damage image, among the images of the plurality of second damages included in the second damage image, is applied to the second laser light. In this case, the aberration can be adjusted so that the damages shown in the second film of the second film wafer more reliably become close to the damage shown in the first film of the first film wafer.

In the laser adjustment method according to the present disclosure, the second laser light may be modulated by a modulation pattern displayed in a spatial light modulator, and in the adjustment process, the modulation pattern may be adjusted to adjust the aberration that is applied to the second laser light. In this way, the aberration that is applied to the laser light can be adjusted by using the spatial light modulator.

### Advantageous Effects of Invention

According to the present disclosure, it is possible to provide a laser adjustment method and a laser processing apparatus capable of suppressing a variation in processing results.

### BRIEF DESCRIPTION OF DRAWINGS

FIG. 1 is a schematic view illustrating a configuration of a laser processing apparatus according to an embodiment.

FIG. 2 is a schematic view illustrating a configuration of a laser irradiation unit illustrated in FIG. 1.

FIG. 3 is a schematic view illustrating a 4f optical system illustrated in FIG. 2.

FIG. 4 is a schematic cross-sectional view illustrating a part of a spatial light modulator illustrated in FIG. 2.

FIG. 5 is a view illustrating an example of an object in laser processing.

FIG. 6 is a view illustrating a film wafer that is used in a laser adjustment method.

FIG. 7 is a view illustrating an example of a damage image.

FIG. 8 is a flowchart illustrating a process of a laser adjustment method according to a first embodiment.

FIG. 9 is a schematic cross-sectional view illustrating the process illustrated in FIG. 8.

FIG. 10 is an example of a modified region and an image of a damage.

FIG. 11 is a flowchart illustrating another process of the laser adjustment method according to the first embodiment.

FIG. 12 is a schematic cross-sectional view illustrating the other process illustrated in FIG. 11.

FIG. 13 is an example of a modified region and an image of a damage.

FIG. 14 is an image table illustrating a relationship between an aberration applied to laser light and a damage.

FIG. 15 is a view illustrating a damage in a case where an astigmatism is applied to laser light.

FIG. 16 is a view illustrating a relationship between the intensity of an astigmatism pattern and a damage.

FIG. 17 is a view illustrating a relationship between the intensity of the astigmatism pattern and the damage.

FIG. 18 is a flowchart illustrating a process of a laser adjustment method according to a second embodiment.

FIG. 19 is a flowchart illustrating another process of the laser adjustment method according to the second embodiment.

FIG. 20 is an image illustrating damages in respective processes of the laser adjustment method according to the second embodiment.

FIG. 21 is a flowchart illustrating a process of a laser adjustment method according to a third embodiment.

FIG. 22 is a first damage image acquired in a first preparation process of the laser adjustment method according to the third embodiment.

FIG. 23 is a flowchart illustrating another process of the laser adjustment method according to the third embodiment.

FIG. 24 is a second damage image acquired in an imaging process of the laser adjustment method according to the third embodiment.

FIG. 25 is a view illustrating trefoil aberration.

FIG. 26 is a flowchart illustrating a process of a laser adjustment method according to a fourth embodiment.

FIG. 27 is an example of a damage image including an image of a damage.

FIG. 28 is a flowchart illustrating another process of the laser adjustment method according to the fourth embodiment.

FIG. 29 is an example of a damage image including an image of a damage.

FIG. 30 is a view illustrating an effect when using the trefoil aberration.

### DESCRIPTION OF EMBODIMENTS

Hereinafter, an embodiment will be described in detail with reference to the drawings. In the drawings, the same or corresponding portions are denoted by the same reference numerals, and redundant description may be omitted. In addition, each drawing may indicate an orthogonal coordinate system defined by an X-axis, a Y-axis, and a Z-axis.

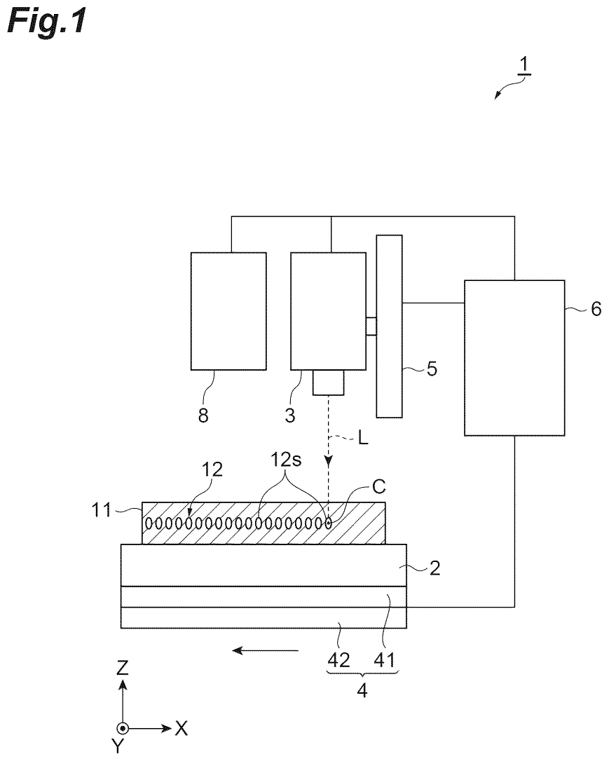

FIG. 1 is a schematic view illustrating a configuration of a laser processing apparatus according to an embodiment. As illustrated in FIG. 1, a laser processing apparatus 1 includes a stage (support unit) 2, a laser irradiation unit 3, drive units (movement units) 4 and 5, a control unit 6, and an imaging unit 8. The laser processing apparatus 1 is an apparatus for forming a modified region 12 in an object 11 by irradiating the object 11 with laser light L.

The stage 2 supports the object 11, for example, by holding a film pasted to the object 11. The stage 2 can rotate around an axial line parallel to the Z-direction as a rotation axis. The stage 2 may be movable along each of the X-direction and the Y-direction. Note that, the X-direction and the Y-direction are a first horizontal direction and a second horizontal direction intersecting (orthogonal to) each other, respectively, and the Z-direction is a vertical direction.

The laser irradiation unit 3 converges the laser light L having permeability with respect to the object 11 and irradiates the object 11 with the laser light L. When the laser light L is converged into the object 11 supported by the stage 2, the laser light L is notably absorbed in a portion corresponding to a converging point C of the laser light L, and the modified region 12 is formed inside the object 11. Note that, the converging point C may be a position where a bean intensity of the laser light L becomes the highest or a region within a predetermined range from a centroid position of the beam intensity as an example.

The modified region 12 is a region that differs from its surrounding unmodified regions in density, refractive index, mechanical strength, and other physical properties. Examples of the modified region 12 include a molten processed region, a crack region, a dielectric breakdown region, a refractive index varying region, and the like. In the modified region 12, a fracture can be formed to be extended from the modified region 12 to the incident side of the laser light L and the opposite side thereof. Such a modified region 12 and a fracture are used, for example, to cut the object 11.

As an example, when the stage 2 is moved along the X-direction and the converging point C is relatively moved with respect to the object 11 along the X-direction, a plurality of modified spots 12s are formed so as to be arranged in a row along the X-direction. One modified spot 12s is formed by irradiation with one pulse of laser light L. One row of modified region 12 is a set of the plurality of modified spots 12s arranged in a row. Adjacent modified spots 12s may be connected to each other or may be separated from each other depending on a relative moving speed of the converging point C with respect to the object 11 and the repetition frequency of the laser light L.

The drive unit 4 includes a first movement unit 41 that moves the stage 2 in one direction in a plane intersecting (orthogonal to) the Z-direction, and a second movement unit 42 that moves the stage 2 in another direction in the plane intersecting (orthogonal to) the Z-direction. As an example, the first movement unit 41 moves the stage 2 along the X-direction, and the second movement unit 42 moves the stage 2 along the Y-direction. In addition, the drive unit 4 rotates the stage 2 around an axial line parallel to the Z-direction as the rotation axis. The drive unit 5 supports the laser irradiation unit 3. The drive unit 5 moves the laser irradiation unit 3 along the X-direction, the Y-direction, and the Z-direction. When the stage 2 and/or the laser irradiation unit 3 are moved in a state in which the converging point C of the laser light L is formed, the converging point C is relatively moved with respect to the object 11. That is, the drive units 4 and 5 are movement units that move at least one of the stage 2 and the laser irradiation unit 3 so that the converging point C of the laser light L relatively moves with respect to the object 11.

The imaging unit 8 images the object 11 supported by the stage 2 with light passing through the object 11 on the basis of control by the control unit 6. As an example, an image that is obtained through imaging by the imaging unit 8 can be provided for alignment of an irradiation position of the laser light L, or can be used for comparison of damages in a laser light adjustment method to be described later, and the like. The imaging unit 8 may be supported to be movable by the drive unit 5 in combination with the laser irradiation unit 3, or may be configured to be movable separately from the laser irradiation unit 3.

For example, the imaging unit 8 is constituted by a halogen lamp and a filter, and can include a light source (not illustrated) that outputs light in a near infrared region, an optical system (not illustrated) including a lens for converging light output from the light source toward the object 11, or the like, a light detection unit (not illustrated) for detecting light that is output from the light source and passes through the object 11, and the like. For example, the light detection unit is constituted by an InGaAs camera, and can detect light in a near infrared region.

The control unit 6 controls operations of the stage 2, the laser irradiation unit 3, the drive units 4 and 5, and the imaging unit 8. The control unit 6 includes a processing unit, a storage unit, and an input receiving unit (not illustrated). The processing unit is configured as a computer device including a processor, a memory, a storage, a communication device, and the like. In the processing unit, the processor executes software (program) read into the memory or the like, and controls reading and writing of data in the memory and the storage, and communication by the communication device. The storage unit is, for example, a hard disk or the like, and stores various pieces of data.

The storage unit can retain, for example, the image obtained by imaging the object 11 by the imaging unit 8. In other words, the control unit 6 including the storage unit is also a retention unit that retains the image. The input receiving unit is an interface unit that displays various pieces of information, and receives input of various pieces of information from a user. The input receiving unit constitutes a graphical user interface (GUI). The input receiving unit can display any of images retained in the storage unit, the images including, for example, the image obtained by imaging the object 11 by the imaging unit 8. Accordingly, the control unit 6 including the input receiving unit is also a display unit for displaying an image.

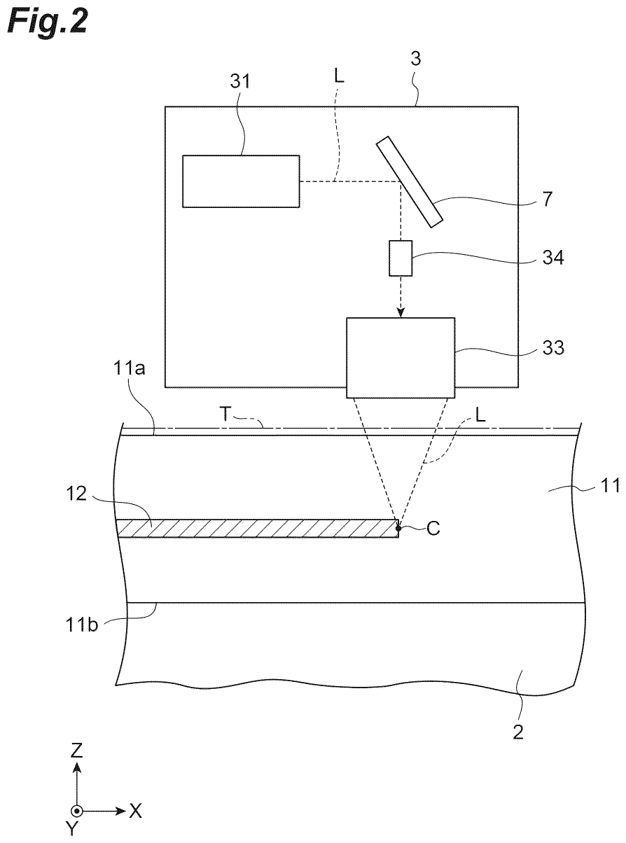

FIG. 2 is a schematic view illustrating a configuration of the laser irradiation unit illustrated in FIG. 1. FIG. 2 illustrates a virtual line T indicating a plan of laser processing. As illustrated in FIG. 2, the laser irradiation unit 3 includes a light source 31, a spatial light modulator 7, a converging lens 33, and a 4f lens unit 34. The light source 31 outputs the laser light L, for example, by a pulse oscillation method. Note that, the laser irradiation unit 3 may not include the light source 31 and may be configured to introduce the laser light L from the outside of the laser irradiation unit 3. The spatial light modulator 7 modulates the laser light L output from the light source 31. The converging lens 33 converges the laser light L modulated by the spatial light modulator 7 and output from the spatial light modulator 7 toward the object 11.

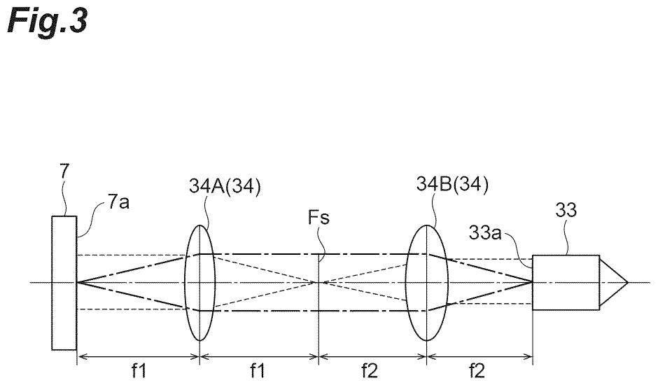

As illustrated in FIG. 3, the 4f lens unit 34 includes a pair of lenses 34A and 34B arranged along an optical path of the laser light L from the spatial light modulator 7 toward the converging lens 33. The pair of lenses 34A and 34B constitutes a both-side telecentric optical system in which a modulation surface 7a of the spatial light modulator 7 and an entrance pupil plane (pupil plane) 33a of the converging lens 33 are in an imaging relationship. According to this, an image of the laser light L on the modulation surface 7a of the spatial light modulator 7 (an image of the laser light L modulated by the spatial light modulator 7) is transferred to (imaged on) the entrance pupil plane 33a of the converging lens 33. Note that, Fs in the drawing indicates a Fourier plane.

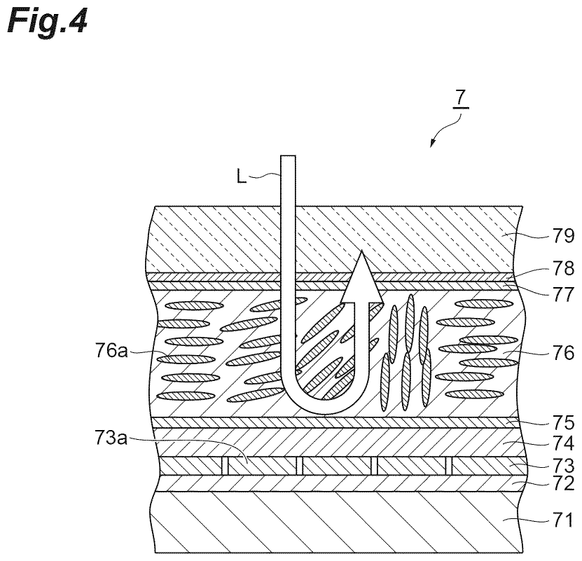

As illustrated in FIG. 4, the spatial light modulator 7 is a spatial light modulator (SLM) of reflective liquid crystal on silicon (LCOS). The spatial light modulator 7 is configured by stacking a drive circuit layer 72, a pixel electrode layer 73, a reflective film 74, an alignment film 75, a liquid crystal layer 76, an alignment film 77, a transparent conductive film 78, and a transparent substrate 79 in this order on a semiconductor substrate 71.

The semiconductor substrate 71 is, for example, a silicon substrate. The drive circuit layer 72 constitutes an active matrix circuit on the semiconductor substrate 71. The pixel electrode layer 73 includes a plurality of pixel electrodes 73a arranged in a matrix along a surface of the semiconductor substrate 71. Each of the pixel electrodes 73a is formed from, for example, a metal material such as aluminum. A voltage is applied to each of the pixel electrodes 73a by the drive circuit layer 72.

The reflective film 74 is, for example, a dielectric multilayer film. The alignment film 75 is provided on a surface of the liquid crystal layer 76 on the reflective film 74 side, and the alignment film 77 is provided on a surface of the liquid crystal layer 76 on a side opposite to the reflective film 74. Each of the alignment films 75 and 77 is formed from, for example, a polymer material such as polyimide, and a contact surface of each of the alignment films 75 and 77 with the liquid crystal layer 76 is subjected to, for example, a rubbing treatment. The alignment films 75 and 77 cause liquid crystal molecules 76a included in the liquid crystal layer 76 to be arranged in a certain direction.

The transparent conductive film 78 is provided on a surface of the transparent substrate 79 on the alignment film 77 side, and faces the pixel electrode layer 73 with the liquid crystal layer 76 and the like interposed therebetween. The transparent substrate 79 is, for example, a glass substrate. The transparent conductive film 78 is formed from, for example, a light transmissive and conductive material such as ITO. The transparent substrate 79 and the transparent conductive film 78 allow the laser light L to pass therethrough.

In the spatial light modulator 7 configured as described above, when a signal indicating a modulation pattern is input from the control unit 6 to the drive circuit layer 72, a voltage corresponding to the signal is applied to each of pixel electrodes 73a, and an electric field is formed between each of the pixel electrodes 73a and the transparent conductive film 78. When the electric field is formed, in the liquid crystal layer 76, the arrangement direction of the liquid crystal molecules 76a varies in each region corresponding to each of the pixel electrodes 73a, and the refractive index varies in each region corresponding to each of the pixel electrodes 73a. This state is a state in which a modulation pattern is displayed on the liquid crystal layer 76. The modulation pattern is for modulating the laser light L.

That is, in a state in which the modulation pattern is displayed on the liquid crystal layer 76, when the laser light L is incident to the liquid crystal layer 76 from the outside through the transparent substrate 79 and the transparent conductive film 78, is reflected by the reflective film 74, and is emitted from the liquid crystal layer 76 to the outside through the transparent conductive film 78 and the transparent substrate 79, the laser light L is modulated in correspondence with the modulation pattern displayed on the liquid crystal layer 76. As described above, according to the spatial light modulator 7, modulation of the laser light L can be made by appropriately setting the modulation pattern to be displayed on the liquid crystal layer 76. Note that, the modulation surface 7a illustrated in FIG. 3 is, for example, the liquid crystal layer 76.

As described above, the laser light L output from the light source 31 is incident to the converging lens 33 through the spatial light modulator 7 and the 4f lens unit 34, and is converged to the inside of the object 11 by the converging lens 33. According to this, the modified region 12 and a fracture extending from the modified region 12 are formed in the object 11 at the converging point C. Further, the control unit 6 controls the drive units 4 and 5 to relatively move the converging point C with respect to the object 11. According to this, the modified region 12 and the fracture are formed along the movement direction of the converging point C.

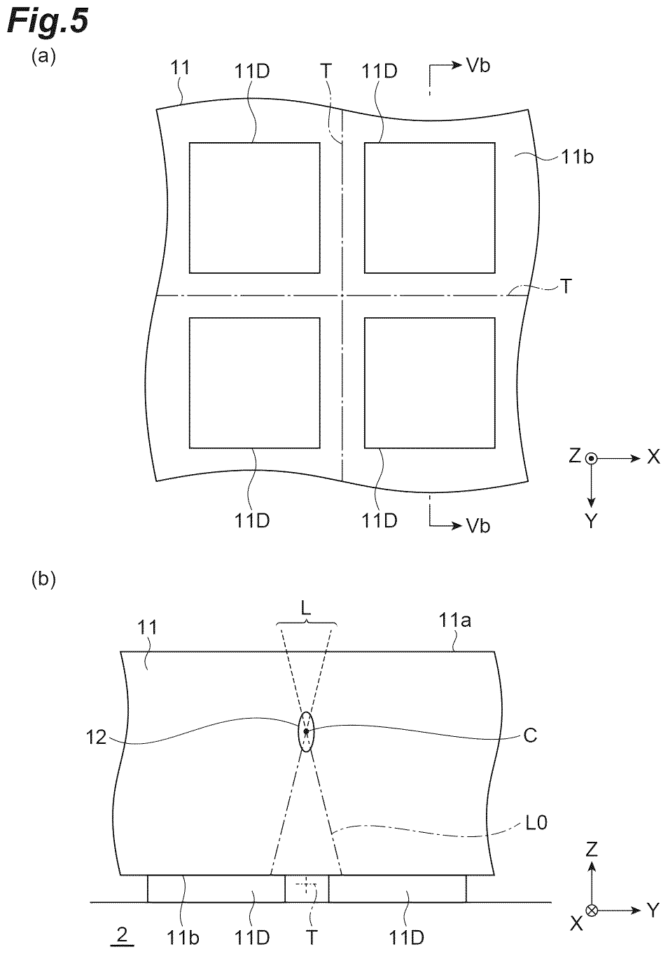

FIG. 5 is a view illustrating an example of an object in laser processing. FIG. 5(a) is a plan view, and FIG. 5(b) is a cross-section view taken along line Vb-Vb in FIG. 5(a). In FIG. 5(b), a state in which the object is supported by the stage is illustrated. In addition, in each cross-sectional view, hatching may be omitted. As illustrated in FIG. 5, the object 11 includes a first surface 11a, and a second surface 11b opposite to the first surface 11a. The object 11 is supported by the stage 2 so that the first surface 11a and the second surface 11b intersect (orthogonal to) the Z-direction, and the first surface 11a faces a laser irradiation unit 3 side. Accordingly, in the object 11, the first surface 11a becomes an incident surface of the laser light L.

The object 11 includes a plurality of semiconductor devices 11D arranged in a two-dimensional shape along the second surface 11b. The following laser processing is performed with respect to such an object 11. First, a converging point C of the laser light L is formed inside the object 11 while the laser light L is incident to the inside of the object 11 from the first surface 11a side. In this state, the object 11 is irradiated with the laser light L while relatively moving the converging point C of the laser light L along the line T in the X-direction. At this time, there is a concern that leaked light L0 of the laser light L on the second surface 11b side may have an influence on the semiconductor device 11D formed on the second surface 11b. Note that, the leaked light L0 stated here occurs when light, which is not reflected from the first surface 11a, is not absorbed to the object 11, and does not contribute to modification of the object 11, in the laser light L emitted to the object 11 reaches the second surface 11b opposite to the first surface 11a of the object 11.

The influence of the leaked light L0 on the semiconductor devices 11D is different depending on the laser processing apparatus 1. In addition, the influence of the leaked light L0 on the semiconductor device 11D may be different depending on an optical system or an apparatus state even in the same laser processing apparatus 1. Accordingly, even in a case where the same laser processing is performed by using laser processing apparatuses 1 different from each other, or even in a case where the same laser processing is performed after adjusting the optical system or the apparatus state although using the same laser processing apparatus 1, there is a concern that a variation may occur in processing results (for example, a yield ratio) (the former case is a processing machine difference). Therefore, here, a laser adjustment method for suppressing a variation in processing results will be described.

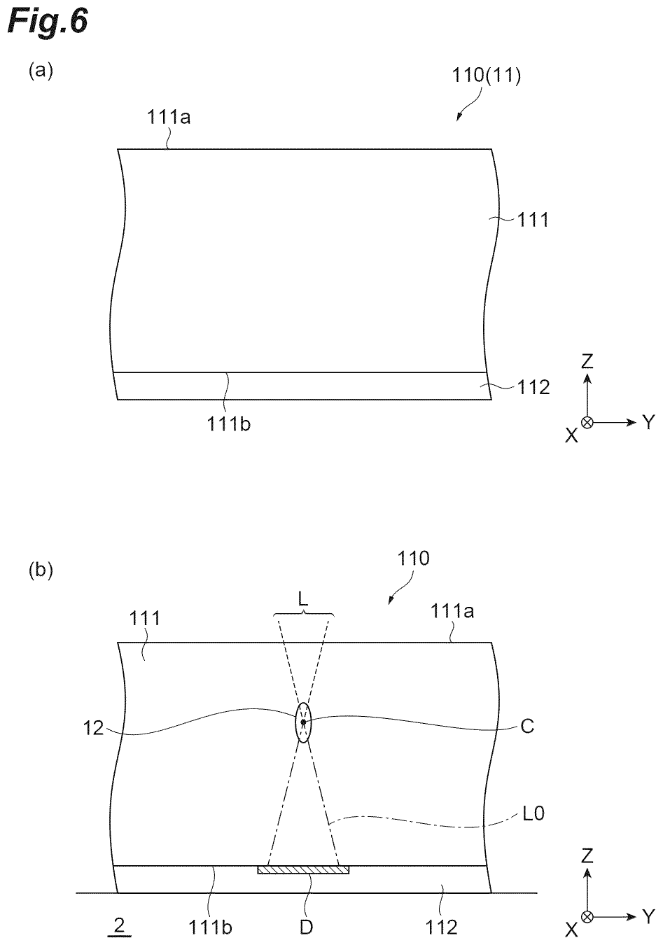

FIG. 6 is a view illustrating a film wafer that is used in the laser adjustment method. FIG. 6(a) is a cross-sectional view of a film wafer, and FIG. 6(b) is a cross-sectional view illustrating a processing aspect of the film wafer. As illustrated in FIG. 6(a), the object 11 stated here is a film wafer 110 including a wafer 111 and a film 112 provided on the wafer 111. More specifically, the film wafer 110 includes a first surface 111a and a second surface 111b opposite to the first surface 111a, and the film 112 is formed on the second surface 111b.

As an example, the wafer 111 can be constituted by a material having a light-transmitting property with respect to the laser light L and the same material as that of an actual laser processing object 11, but may be constituted by a material different from that of the actual laser processing object 11. For example, the wafer 111 is a sapphire substrate or a silicon substrate. As an example, the film 112 can be constituted by a material in which an absorptivity with respect to the laser light L is higher as compared with the wafer 111. For example, the film 112 is a metal film such as tin and gold.

As illustrated in FIG. 6(b), here, the laser light L is incident to the film wafer 110 from the first surface 111a side, and the film wafer 110 is irradiated with the laser light L while forming a converging point C of the laser light L inside the wafer 111. According to this, a damage D is generated in the film 112 due to leaked light L0 of the laser light L. The damage D is generated on a surface of the film 112 on the wafer 111 side. Next, the surface of the film 112 on the wafer 111 side is imaged by using the imaging unit 8 to acquire a damage image including an image of the damage D.

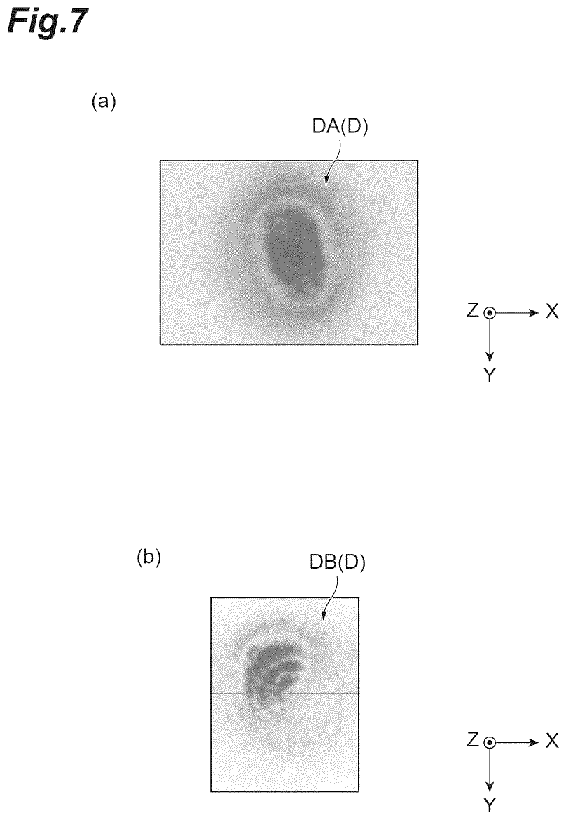

FIG. 7 is a view illustrating an example of the damage image. FIG. 7(a) is a damage image in the laser processing apparatus 1 (apparatus A), and FIG. 7(b) is a damage image in another laser processing apparatus 1 (apparatus B). When comparing an image of a damage DA by the apparatus A as illustrated in FIG. 7(a), and an image of a damage DB by the apparatus B as illustrated in FIG. 7(b), it can be understood that the images are different from each other. In this way, the difference between the damages DA and DB on the film 112 due to the leaked light L0 represents that an influence on a semiconductor device due to the leaked light L0 is different between the apparatus A and the apparatus B, and represents that there is a concern that a variance in processing results may occur.

In the laser adjustment method according to the present disclosure, an aberration that is applied to the laser light L is adjusted to suppress the variation in the processing results. Here, the damage DA in the apparatus A and the damage DB in the apparatus B can be made to be close to each other by adjusting the aberration that is applied to the laser light L. According to this, a difference in an influence on the semiconductor device due to the leaked light L0 is suppressed between the apparatus A and the apparatus B, and as a result, the variation in the processing results is suppressed (a processing machine difference is suppressed). Hereinafter, description will be made in detail.

### First Embodiment

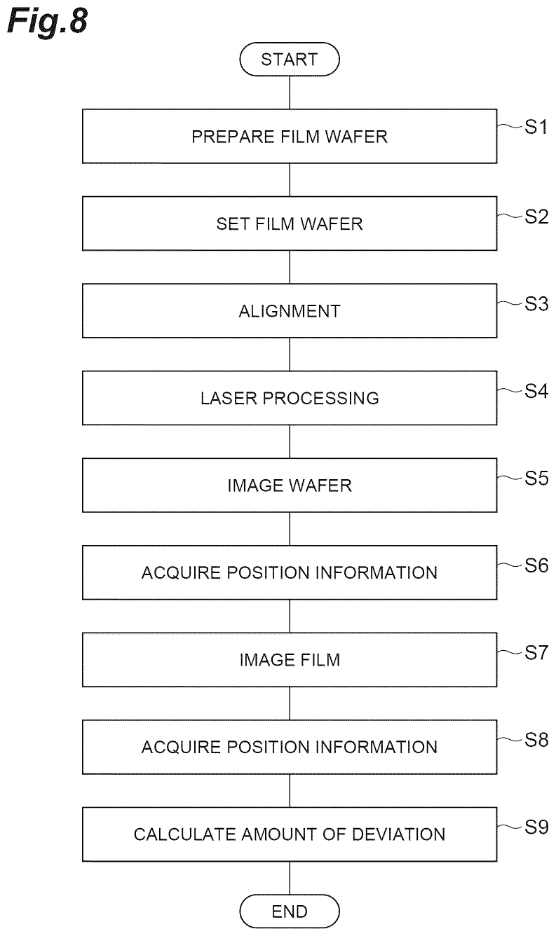

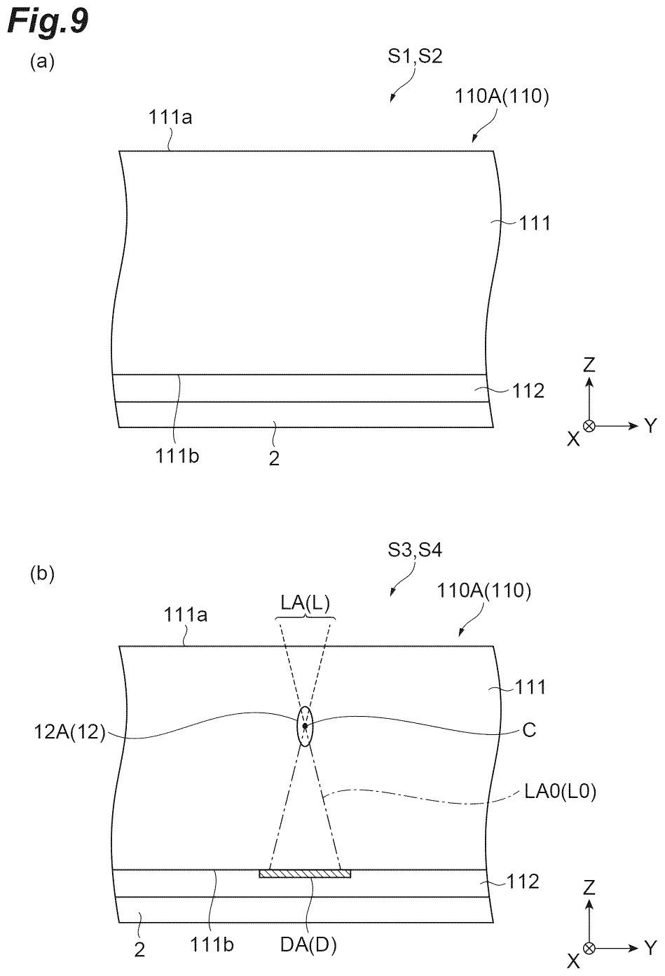

Next, a laser adjustment method according to a first embodiment will be described. FIG. 8 is a flowchart illustrating a process of the laser adjustment method according to the first embodiment. FIG. 9 is a schematic cross-sectional view illustrating the process illustrated in FIG. 8. As illustrated in FIG. 8 and FIG. 9(a), first, a film wafer (first film wafer) 110A is prepared (process S1). The film wafer 110A is similar to the above-described film wafer 110, and includes the wafer 111 (first wafer) and the film (first film) 112.

Next, the film wafer 110A is set in the laser processing apparatus 1 as the apparatus A (process S2). Here, the film wafer 110A is supported by the stage 2 so that the film 112 is located on the stage 2 side, that is, the first surface 111a of the wafer 111 faces the laser irradiation unit 3 side. Note that, the apparatus A is configured to obtain a satisfactory processing result among a plurality of laser processing apparatuses 1 (for example, a yield ratio is high), and is an apparatus that becomes a reference of adjustment.

Next, as illustrated in FIG. 8, alignment and height setting are performed (process S3). As an example, in the process S3, an irradiation position of laser light LA in the X-direction and the Y-direction (direction along the first surface 111a) is determined as alignment and a position of the converging point C of the laser light LA in the Z-direction (direction intersecting the first surface 111a) is adjusted as the height setting on the basis of an image captured by the imaging unit 8. Here, as an example, the height setting can be performed so that the converging point C of the laser light LA is located at the inside of the wafer 111 and becomes a position that matches a position of a converging point C in the Z-direction during actual device processing. The actual device processing represents a case where the object 11 in which the semiconductor devices 11D are formed is irradiated with the laser light L to form the modified region 12 and a fracture, for example, for individualization of the semiconductor devices 11D by using the laser processing apparatus 1.

Next, as illustrated in FIG. 8 and FIG. 9(b), laser processing is performed (process S4). Here, the film wafer 110A is irradiated with the laser light (first laser light) LA from the first surface 111a side of the wafer 111 which is opposite to the film 112. At this time, irradiation with the laser light LA can be performed while relatively moving the converging point C with respect to the film wafer 110A along the X-direction. In this case, the X-direction becomes a processing progress direction. According to this, a modified region (first processing mark) 12A is formed in the wafer 111 in the vicinity of the converging point C of the laser light LA, and the film 112 is irradiated with the leaked light LA0 of the laser light LA and thus a damage (first damage) DA is formed in the film 112. In this way, in the process S4, the control unit 6 controls the laser irradiation unit 3 to perform a process of irradiating the film 112 of the film wafer 110A in a state of being supported by the stage 2 with the laser light LA (the leaked light LA0 that is a part of the laser light LA).

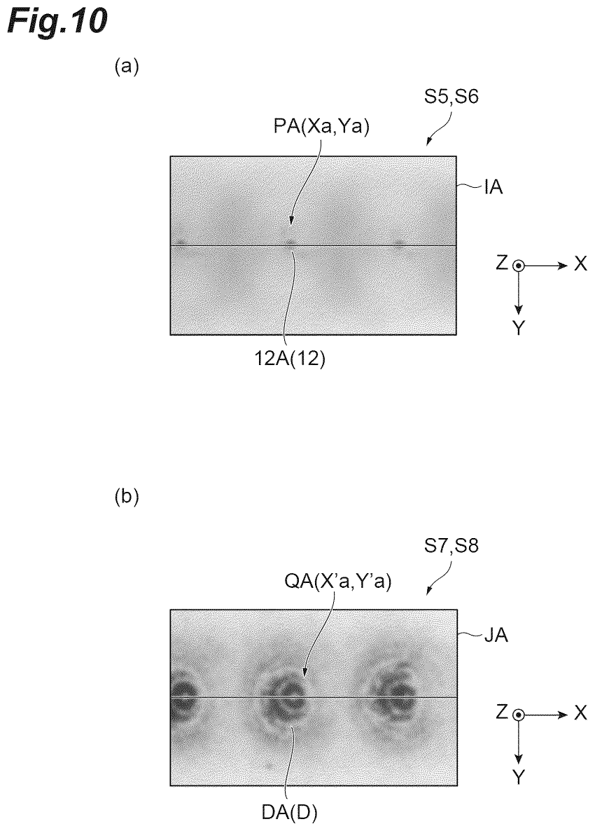

Next, as illustrated in FIG. 8, the wafer 111 is imaged (process S5). According to this, an image as illustrated in FIG. 10(a) is acquired. FIG. 10(a) is an example of a processing image including an image of the modified region 12A. More specifically, in the process S5, the wafer 111 is imaged by the imaging unit 8 at a position in the Z-direction where the modified region 12A is formed in the wafer 111, thereby acquiring a first processing image IA that is an image including the image of the modified region 12A as a first processing mark as illustrated in FIG. 10(a). In this way, in the process S5, the control unit 6 controls the imaging unit 8 to perform a process of imaging the wafer 111, and acquiring the first processing image IA including the image of the modified region 12A.

Next, as illustrated in FIG. 8 and FIG. 10(a), position information of the modified region 12A is acquired on the basis of the first processing image IA captured in the process S5 (process S6). More specifically, in the process S6, information indicating position coordinates PA (Xa, Ya) of the modified region 12A in the X-direction and the Y-direction is acquired with reference to the first processing image IA. Note that, at this time, a process of displaying the first processing image IA may be further performed.

Next, as illustrated in FIG. 8, the film 112 is imaged (process S7). According to this, an image as illustrated in FIG. 10(b) is acquired. FIG. 10(b) is an example of a damage image including an image of the damage DA. More specifically, in the process S7, the film 112 is imaged by the imaging unit 8 at a position (surface of the film 112) in the Z-direction where the damage DA is formed in the film 112, thereby acquiring a first damage image JA that is an image including an image of the damage DA formed by the leaked light LA0 of the laser light LA when forming the modified region 12A. In this way, in the process S7, the control unit 6 controls the imaging unit 8 to perform a process of imaging the film 112, and acquiring the first damage image JA including the image of the damage DA as illustrated in FIG. 10(b).

Next, as illustrated in FIG. 8 and FIG. 10(b), position information of the damage DA is acquired on the basis of the first damage image JA captured in the process S7 (process S8). More specifically, in the process S8, information indicating position coordinates QA (X′a, Y′a) of the center (for example, a centroid) of the damage DA in the X-direction and the Y-direction is acquired with reference to the first damage image JA. Note that, at this time, a display process of displaying the first damage image JA may be further performed.

Next, as illustrated in FIG. 8, the amount and a direction of a deviation between the position of the modified region 12A and the center of the damage DA are calculated (process S9). More specifically, in the process S9, the amount and the direction of the deviation between a position of the image of the modified region 12A included in the first processing image IA and a central position of the image of the damage DA included in the first damage image JA are calculated. The amount and the direction of the deviation can be calculated by using the position coordinates PA (Xa, Ya) of the modified region 12A which are acquired in the process S6, and the position coordinates QA (X′a, Y′a) of the center of the damage DA which are acquired in the process S8.

As described above, in the apparatus A that becomes the reference of adjustment, the first processing image IA including the image of the modified region 12A, the first damage image JA including the image of the damage DA, and the amount and the direction of the deviation between the position of the image of the modified region 12A included in the first processing image IA and the central position of the image of the damage DA included in the first damage image JA are acquired. The acquired information can be shared and retained by the control units 6 (retention units) of a plurality of the laser processing apparatuses 1 including the following laser processing apparatus 1 that is a target of adjustment. The above-described process is a first preparation process of the laser adjustment method according to this embodiment. Note that, here, in the process of the laser adjustment method, the information is acquired by actually performing the laser processing or the imaging. However, the information prepared in advance may be acquired separately. That is, it is not essential to perform the laser processing or the imaging in order to obtain the information as a series of processes of the laser adjustment method.

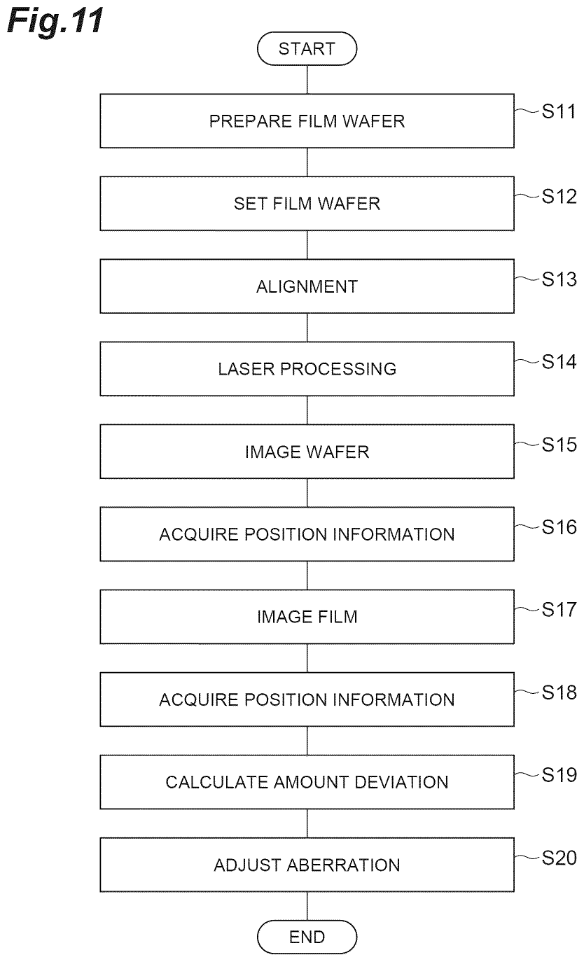

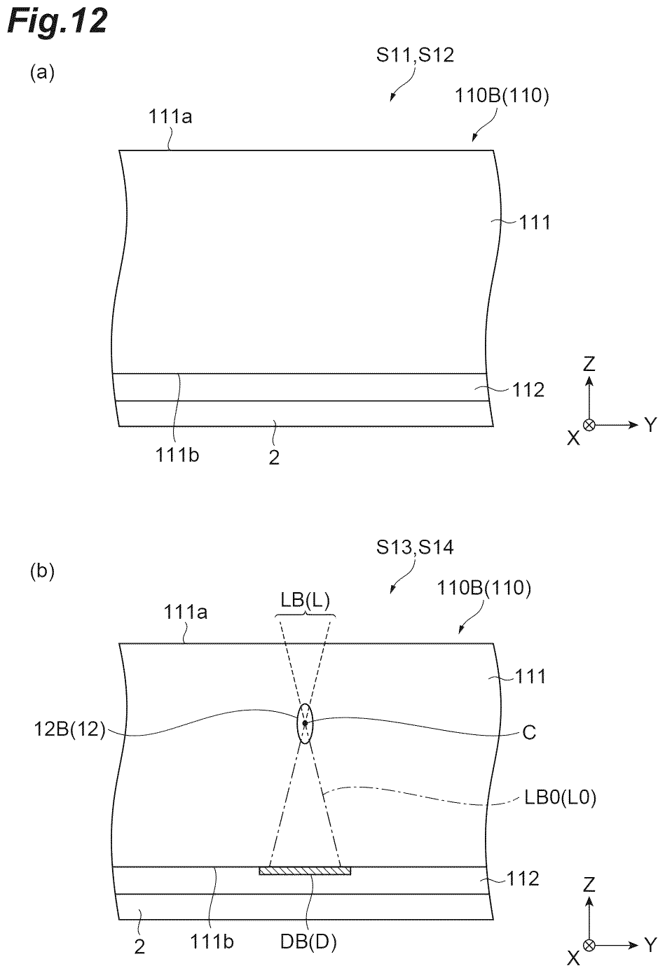

In the laser adjustment method according to this embodiment, subsequently, an aberration of the laser light is adjusted on the basis of the information prepared in the first preparation process. FIG. 11 is a flowchart illustrating another process of the laser adjustment method according to the first embodiment. FIG. 12 is a schematic cross-sectional view illustrating the other process illustrated in FIG. 11.

As illustrated in FIG. 11 and FIG. 12(a), first, a film wafer (second film wafer) 110B is prepared (process S11, second preparation process). The film wafer 110B is similar to the above-described film wafer 110, and includes a wafer 111 (second wafer) and a film (second film) 112. Note that, as the film wafer 110B, the film wafer 110A used in the first preparation process may be used again, and the film wafer 110 different form the film wafer 110A may be prepared.

Next, the film wafer 110B is set in the laser processing apparatus 1 as the apparatus B (process S12). Here, the film wafer 110B is supported by the stage 2 so that the film 112 becomes the stage 2 side, that is, the first surface 111a of the wafer 111 faces the laser irradiation unit 3 side. Note that, the apparatus B is an apparatus that has an inferior processing result (for example, a lower yield ratio) as compared with the apparatus A among the plurality of laser processing apparatuses 1, and is a target of adjustment. Here, description is given on the assumption that the apparatus A and the apparatus B are set as different laser processing apparatuses 1, but the apparatus A and the apparatus B can be set to one state of one laser processing apparatus 1 and another state in which an optical system or an apparatus state are adjusted from the one state.

Next, as illustrated in FIG. 11, alignment and height setting are performed (process S13). As an example, even in the process S13, as in the process S3, an irradiation position of laser light LB in the X-direction and the Y-direction (direction along the first surface 111a) is determined (alignment is performed) on the basis of an image captured by the imaging unit 8, and a position of a converging point C of the laser light LB in the Z-direction (direction intersecting the first surface 111a) is adjusted. Here, as an example, the height setting is performed so that the converging point C of the laser light LB is located inside the wafer 111. In addition, here, it is conceivable to align the converging point C of the laser light LB at the same position as a position where the converging point C of the laser light LA is aligned in the first preparation process at least with respect to the Z-direction.

Next, as illustrated in FIG. 11 and FIG. 12(b), laser processing is performed (process S14, processing process). Here, as in the process S4, the film wafer 110B is irradiated with the laser light (second laser light) LB from the first surface 111a side of the wafer 111 which is opposite to the film 112. At this time, irradiation with the laser light LB can be performed while relatively moving the converging point C with respect to the film wafer 110B along the X-direction. In this case, the X-direction becomes a processing progress direction. According to this, a modified region (second processing mark) 12B is formed in the wafer 111 in the vicinity of the converging point C of the laser light LB, and a damage (second damage) DB is formed in the film 112 due to irradiation of the film 112 with leaked light LB0 of the laser light LB. In this way, in the process S14, the control unit 6 controls the laser irradiation unit 3 to perform a processing process of irradiating the film 112 of the film wafer 110B in a state of being supported by the stage 2 with the laser light LB (leaked light LB0 that is a part of the laser light LB).

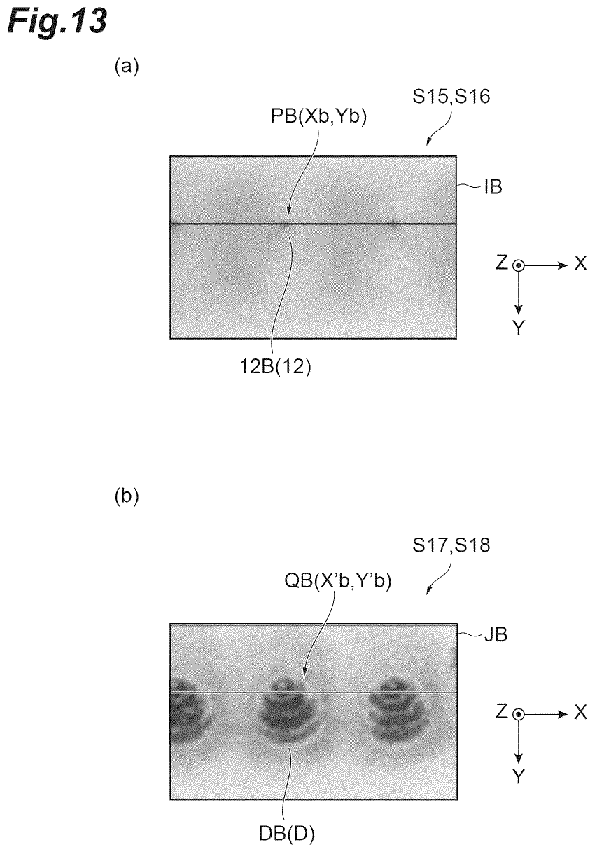

Next, as illustrated in FIG. 11, the wafer 111 is imaged (process S15, imaging process). According to this, an image as illustrated in FIG. 13(a) is acquired. FIG. 13(a) is an example of a processing image including an image of the modified region 12B. More specifically, in the process S15, as in the process S5, the wafer 111 is imaged by the imaging unit 8 at a position in the Z-direction where the modified region 12B is formed in the wafer 111, thereby acquiring a second processing image IB that is an image including the image of the modified region 12B as a second processing mark as illustrated in FIG. 13(a). In this way, in the process S15, the control unit 6 controls the imaging unit 8 to perform a process of imaging the wafer 111, and acquiring the second processing image 2A including the image of the modified region 12B.

Next, as illustrated in FIG. 11 and FIG. 13(a), position information of the modified region 12B is acquired on the basis of the second processing image IB captured in the process S15 (process S16). More specifically, in the process S16, information indicating position coordinates PB (Xb, Yb) of the modified region 12B in the X-direction and the Y-direction is acquired with reference to the second processing image IB. Note that, at this time, a process of displaying the second processing image IB may be further performed.

Next, as illustrated in FIG. 11, the film 112 is imaged (process S17, imaging process). According to this, an image as illustrated in FIG. 13(b) is acquired. FIG. 13(b) is an example of a damage image including an image of the damage DB. More specifically, in the process S17, the film 112 is imaged by the imaging unit 8 at a position (surface of the film 112) in the Z-direction where the damage DB is formed in the film 112, thereby acquiring a second damage image JB that is an image including an image of the damage DB formed by the leaked light LB0 of the laser light LB when forming the modified region 12B as illustrated in FIG. 13(b). In this way, in the process S17, the control unit 6 controls the imaging unit 8 to perform an imaging process of imaging the film 112, and acquiring the second damage image JB including the image of the damage DB.

As illustrated in FIG. 11 and FIG. 13(b), position information of the damage DB is acquired on the basis of the second damage image JB captured in the process S17 (process S18). More specifically, in the process S18, information indicating position coordinates QB (X′b, Y′b) showing the center (for example, a centroid) of the damage DB in the X-direction and the Y-direction is acquired with reference to the second damage image JB. Note that, at this time, a display process of displaying the second damage image JB may be further performed.

Next, as illustrated in FIG. 11, the amount and a direction of a deviation between the position of the modified region 12B and the center of the damage dB are calculated (process S19). More specifically, in the process S19, the amount and the direction of the deviation between the position of the image of the modified region 12B included in the second processing image IB, and the central position of the image of the damage DB included in the second damage image JB. The amount and the direction of the deviation can be calculated by using the position coordinates PB (Xb, Yb) of the modified region 12B which are acquired in the process S16, and the position coordinates QB (X′b, Y′b) of the center of the damage DB which are acquired in the process S18.

Next, an aberration that is applied to the laser light LB is adjusted so that the image of the damage DB included in the second damage image JB becomes close to the image of the damage DA included in the first damage image JA (process S20, adjustment process). In the process S20, as an example, the aberration that is applied to the laser light LB is adjusted by adjusting a modulation pattern that is displayed on a spatial light modulator 7 of the apparatus B. The process S20 will be described in more detail.

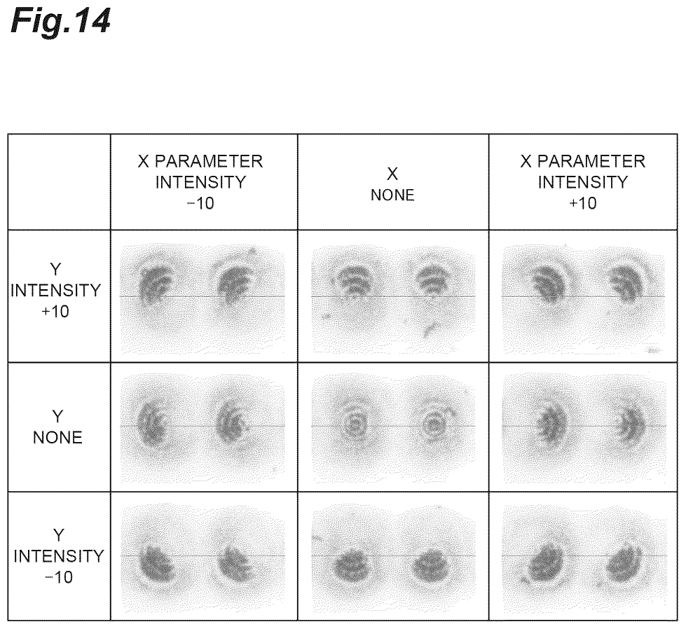

FIG. 14 is a table of images showing a relation between an aberration applied to laser light and a damage. In this example, a relationship between an intensity of a comma aberration pattern (modulation pattern) displayed on the spatial light modulator 7 and a damage is illustrated. That is, in this embodiment, the comma aberration that is applied to the laser light LB is adjusted by adjusting the intensity of the comma aberration pattern that is displayed on the spatial light modulator 7. As illustrated in FIG. 14, it can be understood that when increasing or decreasing the intensity of the comma aberration pattern with respect to the X-direction and the Y-direction, a comma aberration that is applied to the laser light LB is changed, and as a result, a shape of a damage is changed. Note that, the intensity of the modulation pattern relates to the amount of aberration that is applied to the laser light.

Accordingly, in the process S20, the comma aberration that is applied to the laser light LB is adjusted by adjusting the comma aberration pattern that is displayed on the spatial light modulator 7 so that the amount and the direction of the deviation between the position of the image of the modified region 12B included in the second processing image IB and the central position of the image of the damage DB included in the second damage image JB become close to the amount and the direction of the deviation between the position of the image of the modified region 12A included in the first processing image IA and the image of the damage DA included in the first damage image JA. In this way, here, the control unit 6 executes an adjustment process of adjusting the aberration that is applied to the laser light LB by adjusting the modulation pattern so that the image of the damage DB included in the second damage image JB becomes closes to the image of the damage DA included in the first damage image JA.

As a result of the adjustment in the process S20, the image of the damage DB included in the second damage image JB varies from the image of the damage DB illustrated in FIG. 13, and can be made to be close to the damage DA illustrated in FIG. 10. Note that, as a result of the adjustment in the process S20 performed once, in a case where the image of the damage DB is not sufficiently close to the image of the damage DA, the process S14 to the process S20 can be repetitively performed.

In addition, here, as a method of adjusting the comma aberration that is applied to the laser light LB, a method of controlling the comma aberration pattern that is displayed on the spatial light modulator 7 has been exemplified, but the method adjusting the comma aberration that is applied to the laser light LB is not limited thereto. For example, the comma aberration that is applied to the laser light LB can also be adjusted by offsetting a spherical aberration correction pattern that is displayed on the spatial light modulator 7 as a modulation pattern.

More specifically, in the modulation surface 7a of the spatial light modulator 7, the center of the spherical aberration correction pattern is offset in the X-direction and/or the Y-direction with respect to the center of (beam spot) of the laser light LB. As described above, the modulation surface 7a is image-transferred to the entrance pupil plane 33a of the converging lens 33 by the 4f lens unit 34. Accordingly, an offset of the modulation pattern in the modulation surface 7a is inverted and converted into an offset on the entrance pupil plane 33a. Accordingly, the comma aberration that is applied to the laser light LB can be adjusted by adjusting the amount and the direction of the offset of the spherical aberration correction pattern on the modulation surface 7a.

As described above, in the laser adjustment method and the laser processing apparatus 1 according to this embodiment, an image including the image of the damage DA formed in the film 112 of the film wafer 110A that becomes a reference of adjustment is prepared as the first damage image JA. On the other hand, the damage DB is formed by irradiating the film wafer 110B with the laser light LB (leaked light LB0), and the film 112 is imaged to acquire the second damage image JB including an image of the damage DB. In addition, the aberration that is applied to the laser light LB is adjusted so that the image of the damage DB included in the second damage image JB becomes close to the image of the damage DA included in the first damage image JA.

According to this, the damage shown in the film 112 of the film wafer 110B becomes close to the damage shown in the film 112 of the film wafer 110A. That is, a difference in an influence of the leaked light L0 on the semiconductor devices 11D during actual processing is reduced. As a result, even in a case where a plurality of apparatuses exist, when the same adjustment is executed over the plurality of apparatuses with the first damage image JA set as a reference, a variation in processing results between the plurality of apparatuses is suppressed.

In addition, in the laser adjustment method according to this embodiment, in the adjustment process (process S20), the aberration that is applied to the laser light LB may be adjusted so that the image of the damage DB becomes close to the image of the damage DA on the basis of a comparison result between the image of the damage DB included in the second damage image JB and the image of the damage DA included in the first damage image JA. In this way, when performing display and comparison of images, the aberration can be easily and reliably adjusted so that the damage DB becomes close to the damage DA.

In addition, in the laser adjustment method according to this embodiment, in the adjustment process (process S20), a comma aberration that is applied to the laser light LB is adjusted. In this way, when suppressing a variation in processing results, the comma aberration that is applied to the laser light LB can be adjusted.

In addition, in the laser adjustment method according to this embodiment, in the first preparation process (process S1 to S9), the wafer 111 is irradiated with the laser light LA from a surface (first surface 111a) side of the wafer 111 which is opposite to the film 112 to further acquire an image including an image of the modified region 12A (first processing mark) formed in the wafer 111 as the first processing image IA. In addition, the first damage image JA includes an image of the damage DA formed by the leaked light LA0 of the laser light LA when forming the modified region 12A included in the first processing image IA. In addition, in the processing process (S14), the wafer 111 is irradiated with the laser light LB from a surface (first surface 111a) side opposite to the film 112 of the wafer 111 of the film wafer 110B to form the modified region 12B (second processing mark) in the wafer 111 and form the damage DB in the film 112 with the leaked light LB0 of the laser light LB.

In addition, in the imaging process (S15), the wafer 111 of the film wafer 110B is imaged to acquire an image including the image of the modified region 12B as the second processing image IB. In addition, in the adjustment process (process S20), the comma aberration that is applied to the laser light LB is adjusted so that the amount and the direction of the deviation between the position of the image of the modified region 12B included in the second processing image IB and the central position of the image of the damage DB included in the second damage image JB become close to the amount and the direction of the deviation between the position of the image of the modified region 12A included in the first processing image IA and the central position of the image of the damage DA included in the first damage image JA. According to this, the amount and the direction of the deviation between the processing mark (modified region 12B) shown in the wafer 111 of the film wafer 110B and the damage DB shown in the film 112 can be made to be close to those of the film wafer 110A that is a reference. As a result, the variation in the processing results can be reliably suppressed.

### Second Embodiment

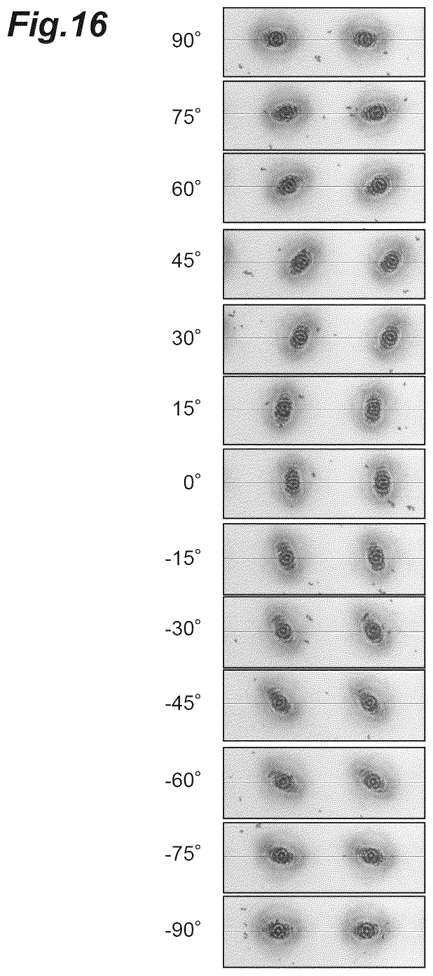

Next, a laser adjustment method according to a second embodiment will be described. In the above-described first embodiment, when suppressing a variation in processing results, the comma aberration that is applied to the laser light LB is adjusted, but when suppressing a variation in processing results, an astigmatism that is applied to the laser light LB can also be adjusted. FIG. 16 is a view illustrating a damage in a case of applying the astigmatism to laser light.

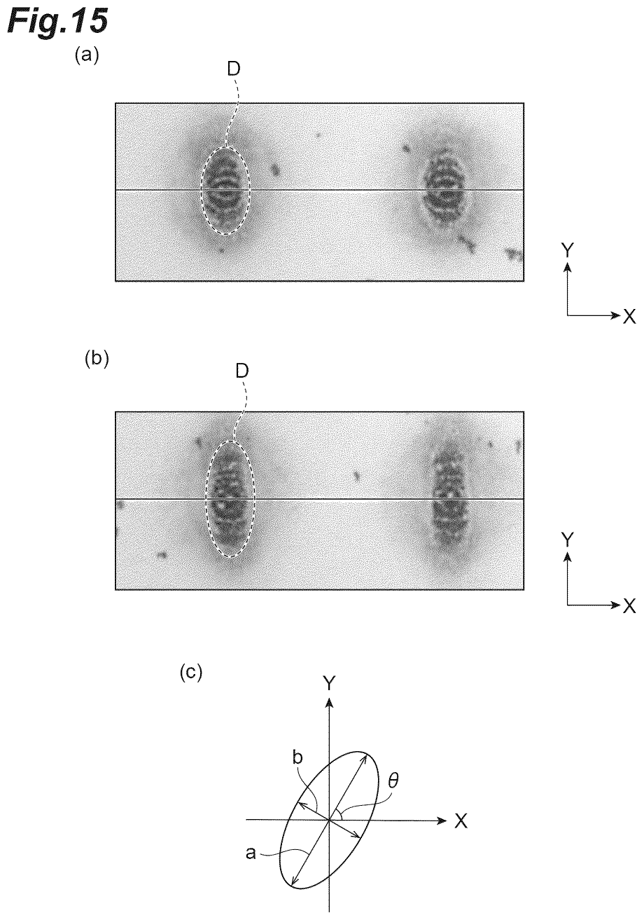

FIG. 15(a) illustrates a damage D in a case where an intensity of an astigmatism pattern displayed on the spatial light modulator 7 is relatively small (for example, in a case where the intensity is 10), and FIG. 15(b) illustrates a damage D in a case where the intensity of the astigmatism pattern displayed on the spatial light modulator 7 is relatively large (for example, in a case where the intensity is 20). As illustrated in FIGS. 15(a) and 15(b), when increasing or decreasing the intensity of the astigmatism pattern, ellipticity ε of the damage D can be adjusted. As an example, the ellipticity ε of the damage D in the case of FIG. 15(a) is approximately 0.59, and the ellipticity ε of the damage D in a case of FIG. 15(b) is approximately 0.43. In addition, the ellipticity ε of the damage D stated here is a value obtained by dividing a length of a short side b of an ellipse illustrated in FIG. 15(c) by a length of a long side a of the ellipse.

In addition, in the example in FIGS. 15(a) and 15(b), an angle θ of the damage D with respect to the X-direction (as an example, a processing progress direction and a reference direction) is set to approximately 90° through adjustment of the astigmatism pattern. The angle of the damage D with respect to the X-direction is set as an angle made between the long side a of the damage D having an elliptical shape and the X-direction as illustrated in FIG. 15(c). Note that, when the angle of the astigmatism pattern is set to 0°, the angle θ of the damage D with respect to the X-direction can be set to 90°.

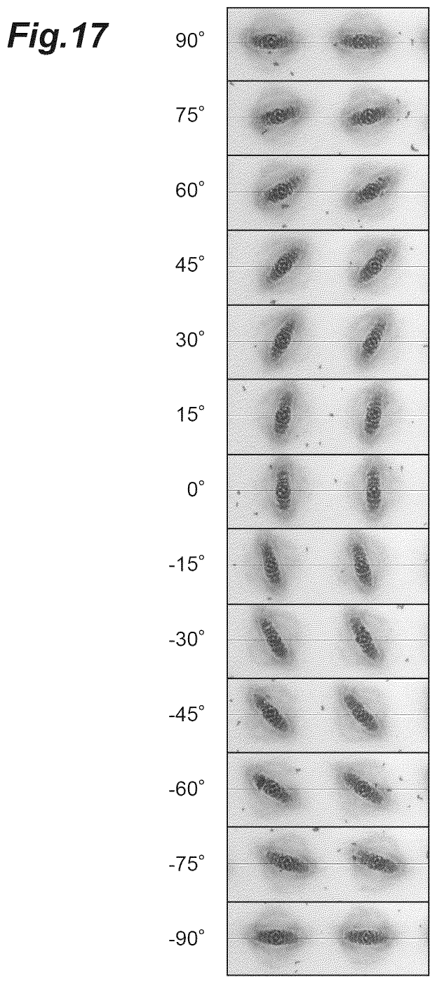

As illustrated in FIG. 16 and FIG. 17, the angle θ of the damage D with respect to the X-direction can be changed from 0° to 180° by adjusting the astigmatism pattern or rotating the pattern. Note that, an example in FIG. 16 illustrates a case where the intensity of the astigmatism pattern is relatively small (for example, a case where the intensity is 10), and an example in FIG. 17 illustrates a case where the intensity of the astigmatism pattern is relatively large (for example, a case where the intensity is 20).

As described above, it can be understood that when adjusting the astigmatism that is applied to laser light, the ellipticity ε of the damage D and the angle θ can be adjusted. Note that, as a method of applying the astigmatism to the laser light, as described above, the astigmatism pattern that is displayed on the spatial light modulator 7 may be used, and a method of adding a cylindrical lens to an optical path of the laser light may also be used.

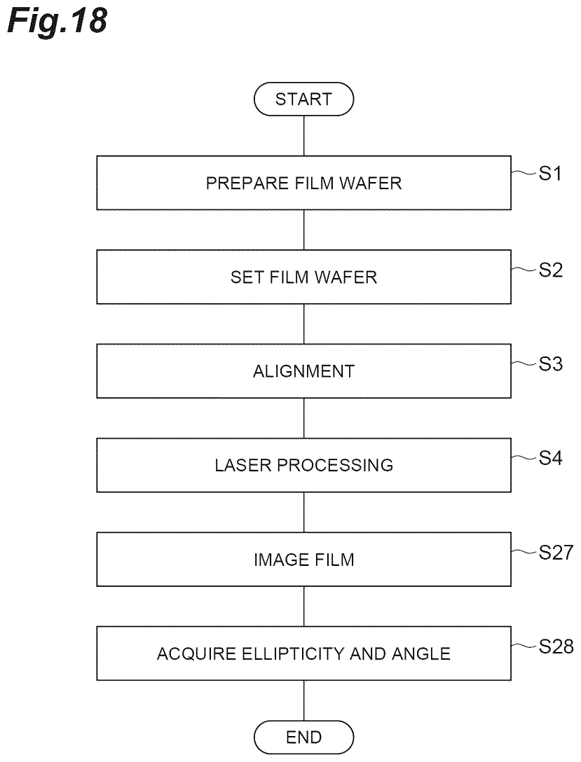

FIG. 18 is a flowchart illustrating a process of the laser adjustment method according to the second embodiment. As illustrated in FIG. 18, in the laser adjustment method according to this embodiment, as in the first embodiment, the film wafer 110A is prepared, and the processes S1 to S4 are performed by using the laser processing apparatus 1 as the apparatus A that is a reference of adjustment. Next, the film 112 of the film wafer 110A is imaged (process S27).

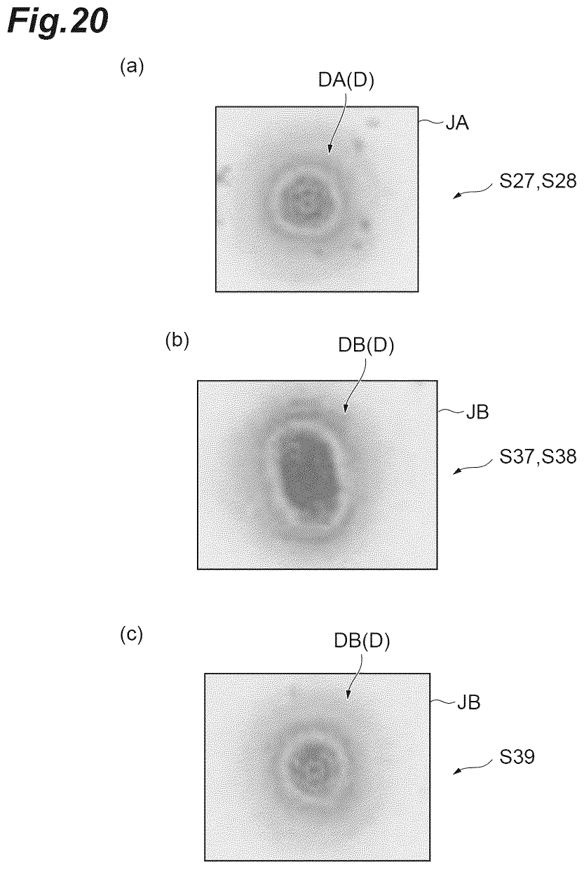

According to this, an image as illustrated in FIG. 20(a) is acquired. FIG. 20(a) is an example of a damage image including an image of a damage DA. More specifically, in a process S27, at a position (surface of the film 112) in the Z-direction where the damage DA is formed in the film 112, the film 112 is imaged by the imaging unit 8, thereby acquiring a first damage image JA that is an image including an image of the damage DA formed by leaked light LA0 of laser light LA when forming a modified region 12A as illustrated in FIG. 20(a). In this way, in the process S27, the control unit 6 controls the imaging unit 8 to perform a process of imaging the film 112, and acquiring the first damage image JA including the image of the damage DA.

Next, as illustrated in FIG. 18, a first angle that is an angle θ of an image of a damage DA included in the first damage image JA with respect to the X-direction (reference direction) and a first ellipticity that is an ellipticity ε of the image of the damage DA are acquired with reference to the first damage image. As described above, in the apparatus A that is a reference of adjustment, the first damage image JA including the image of the damage DA and information relating to the first ellipticity of the damage DA and the first angle are acquired. The acquired information can be shared and retained by the control units (retention units) of a plurality of the laser processing apparatuses 1 including a laser processing apparatus 1 that is a target of adjustment. The above-described process is a first preparation process of the laser adjustment method according to this embodiment.

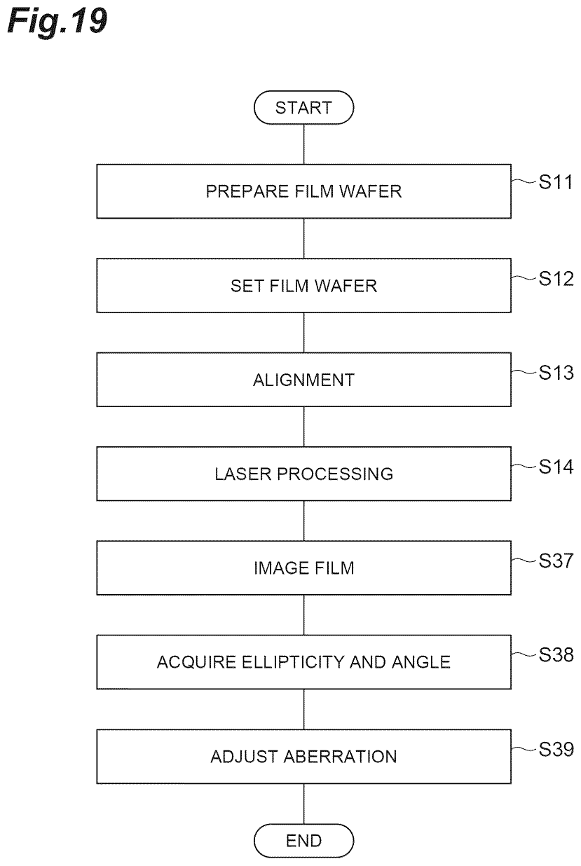

In the laser adjustment method according to this embodiment, adjustment of the aberration of the laser light is subsequently performed on the basis of the information prepared in the first preparation process. FIG. 19 is a flowchart illustrating another process of the laser adjustment method according to the second embodiment. As illustrated in FIG. 19, in the laser adjustment method according to this embodiment, as in the first embodiment, the film wafer 110B is prepared, and the processes S11 to S14 are performed by using the laser processing apparatus 1 as the apparatus B that is a target of adjustment. Next, the film 112 of the film wafer 110B is imaged (process S37).

According to this, an image as illustrated in FIG. 20(b) is acquired. FIG. 20(b) is an example of a damage image including an image of the damage DB. More specifically, in the process S37, the film 112 is imaged by the imaging unit 8 at a position (surface of the film 112) in the Z-direction where the damage DB is formed in the film 112, thereby acquiring a second damage image JB that is an image including an image of the damage DB formed by the leaked light LB0 of the laser light LB when forming the modified region 12B as illustrated in FIG. 20(b). In this way, in the process S37, the control unit 6 controls the imaging unit 8 to perform an imaging process of imaging the film 112, and acquiring the second damage image JB including the image of the damage DB.

Next, as illustrated in FIG. 19, a second angle that is an angle θ of the image of the damage DB included in the second damage image JB with respect to the X-direction (reference direction) and a second ellipticity that is an ellipticity ε of the image of the damage DB are acquired with reference to the second damage image JB (process S38).

Then, the aberration that is applied to the laser light LB is adjusted so that the image of the damage DB included in the second damage image JB becomes close to the image of the damage DA included in the first damage image JA (process S39, adjustment process). More specifically, in the process S39, the astigmatism that is applied to the laser light LB is adjusted so that the second angle and the second ellipticity of the damage DB included in the second damage image JB become close to the first angle and the first ellipticity of the damage DA included in the first damage image JA. Here, as described above, the astigmatism that is applied to the laser light LB can be adjusted by adjusting the astigmatism pattern displayed on the spatial light modulator 7.

FIG. 20(c) is an image showing the damage DB after the adjustment. As illustrated in FIG. 20(c), as a result of the adjustment in the process S39, it can be understood that the image of the damage DB included in the second damage image JB varies from the image of the damage DB illustrated in FIG. 20(b), and becomes close to the damage DA illustrated in FIG. 20(a). Note that, as a result of the adjustment in the process S39 performed once, in a case where the image of the damage DB is not sufficiently close to the image of the damage DA, the process S14 to the process S20 can be repetitively performed.

As described above, in the laser adjustment method and the laser processing apparatus 1 according to this embodiment, in the adjustment process (process S39), the astigmatism that is applied to the laser light LB is adjusted. In this way, when suppressing a variation in processing results, the astigmatism that is applied to the laser light LB may be adjusted.

Particularly, in the laser adjustment method and the laser processing apparatus 1 according to this embodiment, in the first preparation process (processes S1 to S4, S27, and S28), the first angle and the first ellipticity of the image of the damage DA included in the first damage image JA are further acquired, and in the adjustment process (process S39), the astigmatism that is applied to the laser light LB is adjusted so that the second angle and the second ellipticity of the image of the damage DB included in the second damage image JB become close to the first angle and the first ellipticity. According to this, the angle θ and the ellipticity ε of the damage DB can be made to be close to those of the first film that is a reference. As a result, the variation in the processing results can be reliably suppressed.

### Third Embodiment

Next, a laser adjustment method according to a third embodiment will be described. In the first embodiment and the second embodiment, when suppressing the variation in the processing results, the comma aberration and the astigmatism which are applied to the laser light LB are adjusted, but when suppressing the variation in the processing results, a spherical aberration that is applied to the laser light LB can also be adjusted.

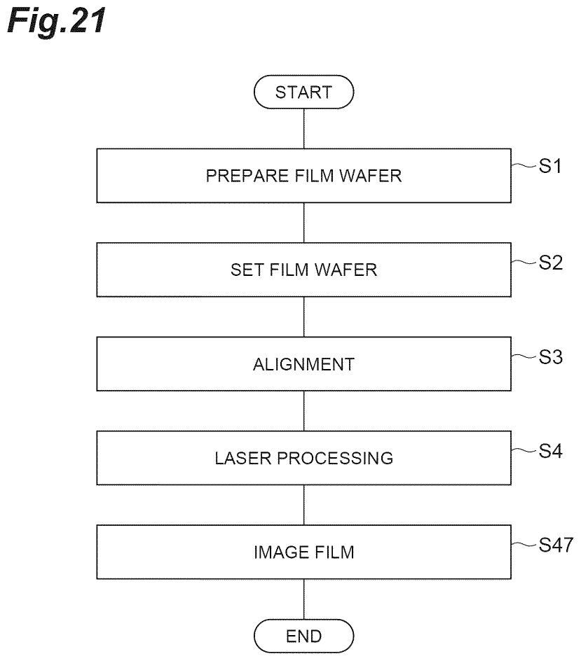

FIG. 21 is a flowchart illustrating a process of the laser adjustment method according to the third embodiment. As illustrated in FIG. 21, in the laser adjustment method according to this embodiment, as in the first embodiment and the second embodiment, the film wafer 110A is prepared, and the processes S1 to S4 are performed by using the laser processing apparatus 1 as the apparatus A that is a reference of adjustment. Next, the film 112 of the film wafer 110A is imaged (process S47).

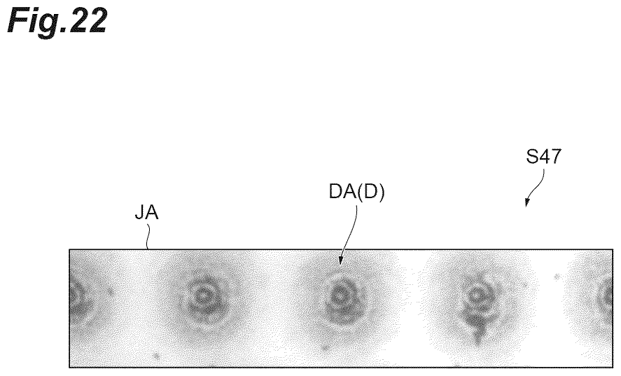

According to this, an image as illustrated in FIG. 22 is acquired. FIG. 22 is an example of a damage image including an image of the damage DA. More specifically, in a process S47, the film 112 is imaged by the imaging unit 8 at a position (surface of the film 112) in the Z-direction where the damage DA is formed in the film 112, thereby acquiring a first damage image JA that is an image including an image of the damage DA formed by leaked light LA0 of laser light LA when forming a modified region 12A as illustrated in FIG. 22.

In this way, in the process S47, the control unit 6 controls the imaging unit 8 to perform a process of imaging the film 112, and acquiring the first damage image JA including the image of the damage DA. As described above, in the apparatus A that is a reference of adjustment, information relating to the first damage image JA including the image of the damage DA is acquired. The acquired information can be shared and retained by the control units (retention units) of a plurality of the laser processing apparatuses 1 including a laser processing apparatus 1 that is a target of adjustment. The above-described process is a first preparation process of the laser adjustment method according to this embodiment.

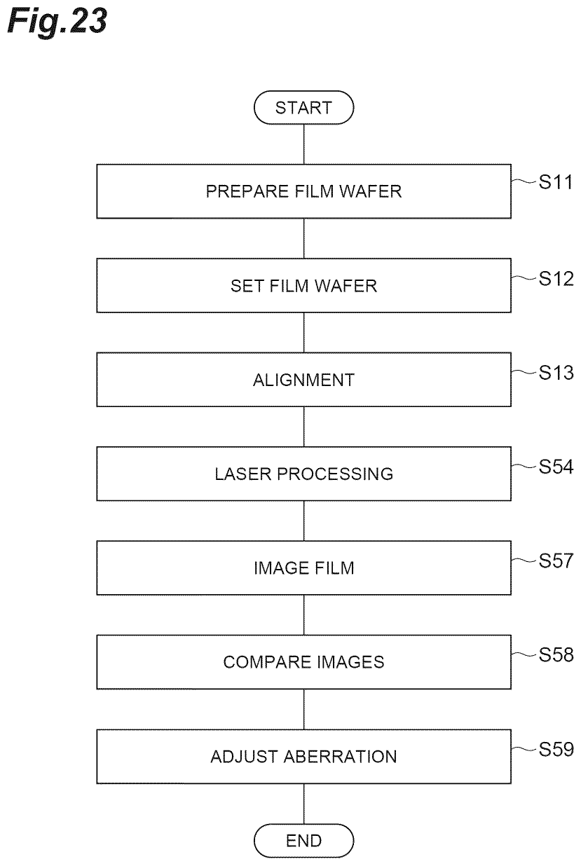

In the laser adjustment method according to this embodiment, an aberration of laser light is subsequently adjusted on the basis of the information prepared in the first preparation process. FIG. 23 is a flowchart illustrating another process of the laser adjustment method according to the third embodiment. As illustrated in FIG. 23, in the laser adjustment method according to this embodiment, as in the first embodiment and the second embodiment, the film wafer 110B is prepared and the processes S11 to S13 are performed by using the laser processing apparatus 1 that is the apparatus B that is a target of adjustment.

Next, laser processing is performed (process S54, processing process). Here, as in the process S14, the film wafer 110B is irradiated with laser light (second laser light) LB from the first surface 111a side of the wafer 111 which is opposite to the film 112. According to this, a modified region (second processing mark) 12B is formed in the wafer 111 in the vicinity of a converging point C of the laser light LB, and the film 112 is irradiated with leaked light LB0 of the laser light LB and thus a damage (second damage) DB is formed in the film 112.

Particularly, in the process S54, the film 112 is irradiated with the laser light LB (leaked light LB0 that is a part of the laser light LB) a plurality of times while varying the spherical aberration that is applied to the laser light LB, thereby forming a plurality of the damages DB in the film 112. More specifically, for example, irradiation (scanning) with the laser light LB is performed while relatively moving the converging point C in the X-direction along one line T while modulating the laser light LB by displaying a spherical aberration correction pattern in a certain amount of correction as a modulation pattern on the spatial light modulator 7. Separately, irradiation (scanning) with the laser light LB is performed while relatively moving the converging point C in the X-direction along another line T while modulating the laser light LB by displaying a spherical aberration correction pattern in a different amount of correction on the spatial light modulator 7. A plurality of rows of damages DB are formed in the film 112 by repeating the irradiation while varying the amount of correction of the spherical aberration correction pattern. According to this, the plurality of damages DB can be formed while varying the spherical aberration that is applied to the laser light LB.

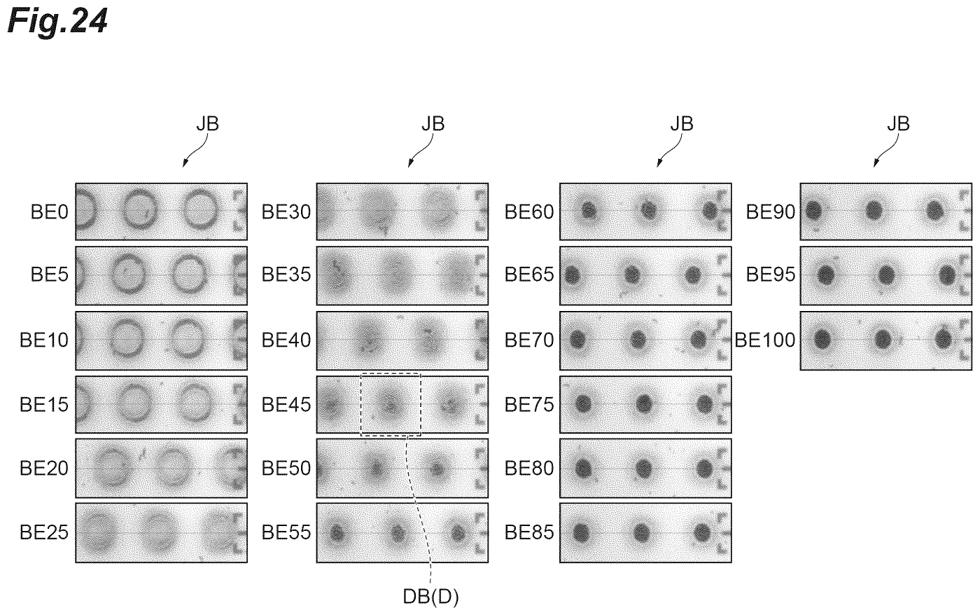

Next, the film 112 of the film wafer 110B is imaged (process S57). According to this, an image as illustrated in FIG. 24 is acquired. FIG. 24 is an example of a damage image including an image of the damage DB. More specifically, in the process S57, the film 112 is imaged by the imaging unit 8 at a position (surface of the film 112) in the Z-direction where the damage DB is formed in the film 112, and a position in the X-direction and the Y-direction of each of a plurality of damages DB, thereby acquiring a plurality of second damage images JB which are images including an image of the damage DB formed by leaked light LB0 of the laser light LB when forming the modified region 12B as illustrated in FIG. 24. Note that, in FIG. 24, an intensity (BE) of the spherical aberration corresponding to each of the second damage images JB is displayed.

Next, the first damage image JA and the plurality of second damage images JB are compared with each other, and an image of the damage DB, which is the closest to the image of the damage DA included in the first damage image JA, among images of the damages DB included in the plurality of second damage images JB, is extracted (process S58).

Then, an aberration that is applied to the laser light LB is adjusted so that the image of the damage DB included in the second damage image JB becomes close to the image of the damage DA included in the first damage image JA (process S59, adjustment process). More specifically, the spherical aberration is adjusted so that the spherical aberration that is applied to the laser light LB becomes a spherical aberration when forming the damage DB that is extracted in the process S58 and is closest to the damage DA. That is, here, the aberration that is applied to the laser light LB is adjusted so that a spherical aberration when forming the damage DB, which is relatively closest to an image of the damage DA included in the first damage image JA, among images of the plurality of damages DB included in the second damage image JB is applied to the laser light LB. Therefore, here, it is possible to adjust a spherical aberration correction pattern that is displayed on the spatial light modulator 7.

As described above, in the laser adjustment method and the laser processing apparatus 1 according to this embodiment, in the adjustment process (process S59), the spherical aberration that is applied to the laser light LB is adjusted. In this manner, when suppressing a variation in processing results, the spherical aberration that is applied to the laser light LB may be adjusted.

Particularly, in the laser adjustment method and the laser processing apparatus 1 according to this embodiment, in the processing process (process S54), the film 112 is irradiated with the laser light LB a plurality of times while varying the spherical aberration that is applied to the laser light LB, thereby forming the plurality of damages DB in the film 112. In addition, in the imaging process (S57), the film 112 is imaged to acquire a plurality of the second damage images JB including images of the plurality of damages DB. Then, in the adjustment process (process S59), the aberration that is applied to the laser light LB is adjusted so that a spherical aberration when forming the damage DB, which is relatively closest to an image of the damage DA included in the first damage image JA, among images of the plurality of damages DB included in the second damage image JB is applied to the laser light LB. According to this, the aberration can be adjusted so that the damage DB that is shown in the film 112 of the film wafer 110B becomes more reliably close to the damage DA that is shown in the film 112 of the film wafer 110A.

### Fourth Embodiment

Next, a laser adjustment method according to a fourth embodiment will be described. In the first embodiment, the second embodiment, and the third embodiment, when suppressing a variation in processing results, the comma aberration, the astigmatism, and the spherical aberration which are applied to the laser light LB are adjusted, but when suppressing the variation in the processing results, a trefoil aberration that is applied to the laser light LB can also be adjusted.

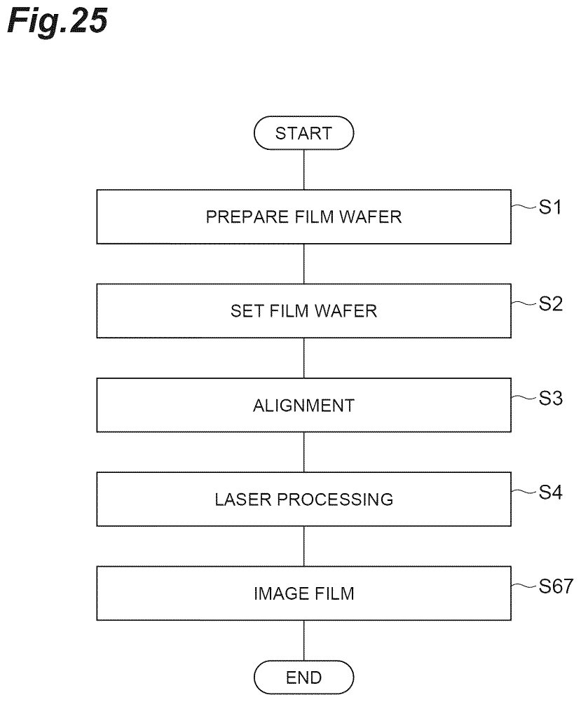

FIG. 25 is a view illustrating the trefoil aberration. FIG. 25(a) is a view illustrating an example of a trefoil aberration pattern for applying the trefoil aberration. FIG. 25(b) is a view illustrating a shape of a converging point in a case where the trefoil aberration is applied. As illustrated in FIG. 25, the trefoil aberration can be applied by displaying a trefoil aberration pattern Pt on the spatial light modulator 7. The trefoil aberration is one of Zernike's third-order aberrations. Note that, the spherical aberration and the astigmatism are included in Zernike's second-order aberrations, and the comma aberration and the trefoil aberration are included in the Zernike's third-order aberrations.

When laser light L modulated by the spatial light modulator 7 displaying the trefoil aberration pattern is converged by the converging lens 33, as illustrated in FIG. 25(b), the laser light L is focused at the converging point C. At this time, a beam shape of the laser light L at the converging point C becomes a beam shape Ct including a central portion C0, and a first extension portion C1, a second extension portion C2, and a third extension portion C3 which radially extend from the central portion C0, and has the highest intensity at the central portion C0. As an example, a width of each of the first extension portion C1, the second extension portion C2, and the third extension portion C3 becomes smaller as being far away from the central portion C0, and the intensity of each of the first extension portion C1, the second extension portion C2, and the third extension portion C3 becomes lower as being far away from the central portion C0. As an example, the beam shape Ct of the laser light L is a shape in which respective sides of a triangle are curved inward.

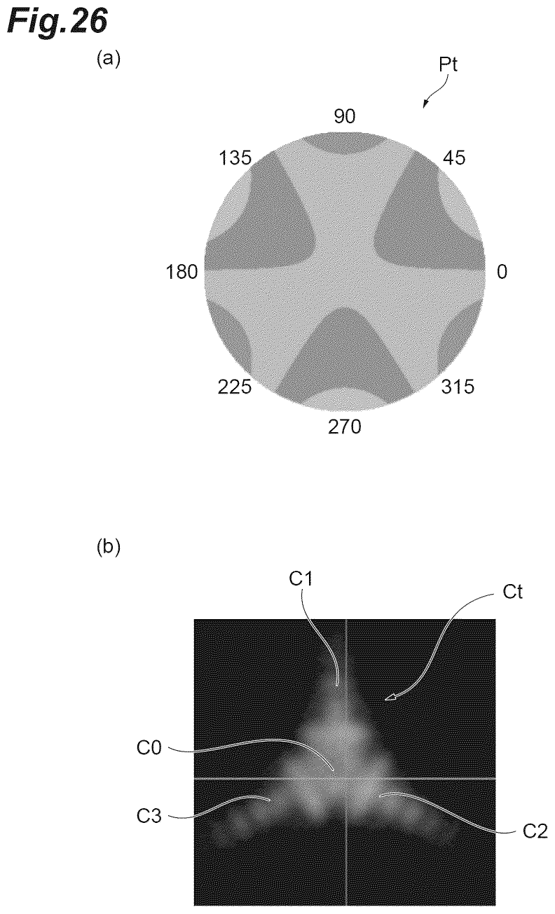

FIG. 26 is a flowchart illustrating a process of the laser adjustment method according to the fourth embodiment. As illustrated in FIG. 26, in the laser adjustment method according to this embodiment, as in the first embodiment and the second embodiment, the film wafer 110A is prepared, and the processes S1 to S4 are performed by using the laser processing apparatus 1 as the apparatus A that is a reference of adjustment. Next, the film 112 of the film wafer 110A is imaged (process S67).

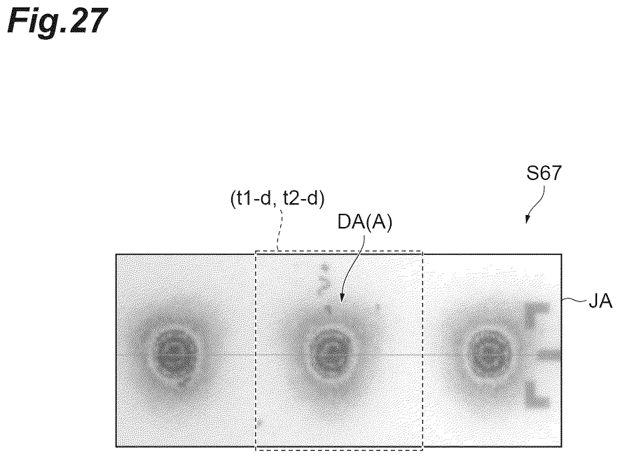

According to this, an image illustrated in FIG. 27 is acquired. FIG. 27 is an example of a damage image including an image of a damage DA. More specifically, in the process S67, the film 112 is imaged by the imaging unit 8 at a position (surface of the film 112) in the Z-direction where the damage DA is formed in the film 112, thereby acquiring a first damage image JA that is an image including an image of the damage DA formed by leaked light LA0 of laser light LA when forming a modified region 12A as illustrated in FIG. 27.

In this way, in the process S67, the control unit 6 controls the imaging unit 8 to perform a process of imaging the film 112, and acquiring the first damage image JA including the image of the damage DA. As described above, in the apparatus A that is a reference of adjustment, information relating to the first damage image JA including the image of the damage DA is acquired. The acquired information can be shared and retained by the control units (retention units) of a plurality of the laser processing apparatuses 1 including the following laser processing apparatus 1 that is a target of adjustment. The above-described process is a first preparation process of the laser adjustment method according to this embodiment. In addition, in the process S67, parameters of the trefoil aberration pattern are set as (t1-d, t2-d). This represents a state in which each of two parameters (for example, trefoil aberration intensities) t1 and t2 specifying the trefoil aberration pattern is set to “d”.

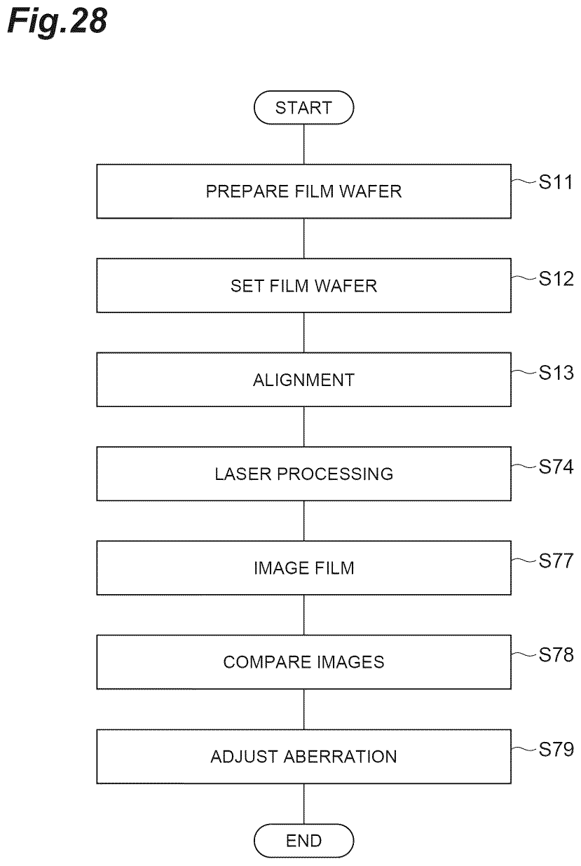

In the laser adjustment method according to this embodiment, an aberration of laser light is subsequently adjusted on the basis of the information prepared in the first preparation process. FIG. 28 is a flowchart illustrating another process of the laser adjustment method according to the fourth embodiment. As illustrated in FIG. 28, in the laser adjustment method according to this embodiment, as in the first embodiment and the second embodiment, the film wafer 110B is prepared and the processes S11 to S13 are performed by using the laser processing apparatus 1 as the apparatus B that is a target of adjustment.

Next, laser processing is performed (process S74, processing process). Here, as in the process S14, the film wafer 110B is irradiated with laser light (second laser light) LB from the first surface 111a side of the wafer 111 which is opposite to the film 112. According to this, a modified region 12B (second processing mark) is formed in the wafer 111 in the vicinity of the converging point C of the laser light LB, and a damage (second damage) DB is formed in the film 112 due to irradiation of the film 112 with leaked light LB0 of the laser light LB.

Particularly, in the process S74, the film 112 is irradiated with the laser light LB (leaked light LB0 that is a part of the laser light LB) a plurality of times while varying the trefoil aberration that is applied to the laser light LB, thereby forming a plurality of the damages DB in the film 112. More specifically, for example, irradiation (scanning) with the laser light LB is performed while relatively moving the converging point C in the X-direction along one line T while modulating the laser light LB by displaying a trefoil aberration pattern in a certain trefoil aberration intensity as a modulation pattern on the spatial light modulator 7. Separately, irradiation (scanning) with the laser light LB is performed while relatively moving the converging point C in the X-direction along another line T while modulating the laser light LB by displaying a trefoil aberration pattern in a different trefoil aberration intensity on the spatial light modulator 7. A plurality of rows of damages DB are formed in the film 112 by repeating the irradiation while varying the trefoil aberration. According to this, the plurality of damages DB can be formed while varying the trefoil aberration that is applied to the laser light LB.

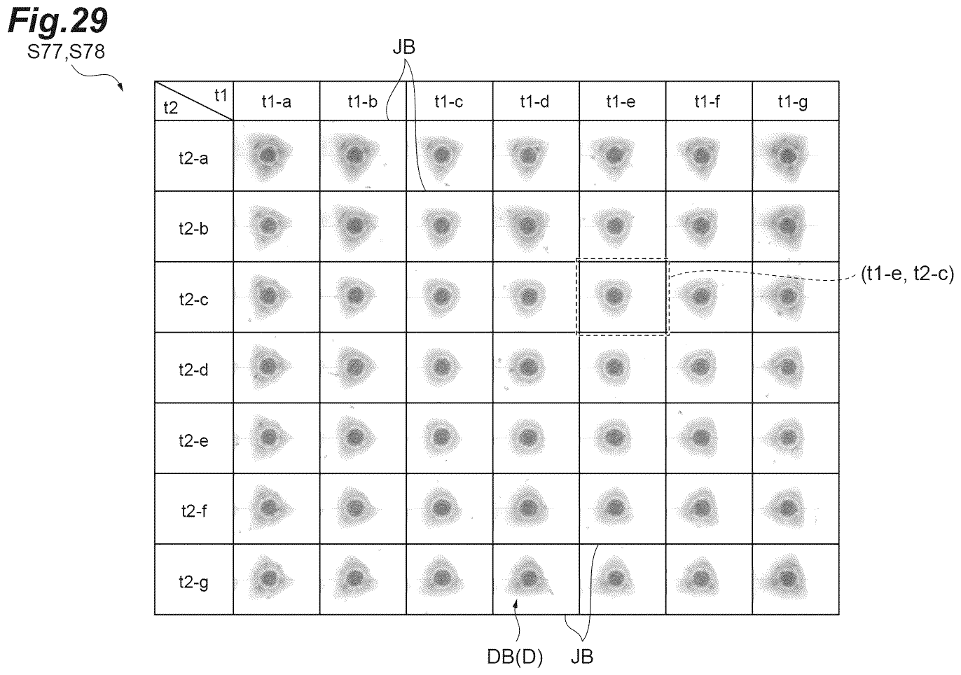

Next, the film 112 of the film wafer 110B is imaged (process S77). According to this, an image as illustrated in FIG. 29 is acquired. FIG. 29 is an example of a damage image including an image of the damage DB. More specifically, in the process S77, the film 112 is imaged by the imaging unit 8 at a position (surface of the film 112) in the Z-direction where the damage DB is formed in the film 112, and a position in the X-direction and the Y-direction of each of a plurality of damages DB, thereby acquiring a plurality of second damage images JB which are images including an image of the damage DB formed by leaked light LB0 of the laser light LB when forming the modified region 12B as illustrated in FIG. 29. In addition, in FIG. 29, corresponding trefoil aberration intensities (the parameters (t1-α, t2-β)) with respect to the second damage images JB are displayed (here, α and β can take values a to g independently of each other) are displayed.

Next, the first damage image JA and the plurality of second damage images JB are compared with each other, and an image of the damage DB, which is the closest to the image of the damage DA included in the first damage image JA, among images of the damages DB included in the plurality of second damage images JB, is extracted (process S78). In this example, an image of the damage DB when the trefoil aberration intensity is (t1-e, t2-c) is extracted as the image closest to the image of the damage DA included in the first damage image JA. In other words, in this example, the same processing as in the apparatus A can be performed by the apparatus B by applying the trefoil aberration pattern in which the trefoil aberration intensity is set to (t1-e, t2-c) to the laser light LB, and thus a machine difference is suppressed.

In the subsequent process, the aberration that is applied to the laser light LB is adjusted so that the image of the damage DB included in the second damage image JB becomes close to the image of the damage DA included in the first damage image JA (process S79, adjustment process). More specifically, the trefoil aberration is adjusted so that the trefoil aberration that is applied to the laser light LB becomes the trefoil aberration when forming the damage DB closest to the damage DA extracted in the process S78. That is, here, the aberration that is applied to the laser light LB is adjusted so that the trefoil aberration when forming the damage DB, which is relatively close to the image of the damage DA included in the first damage image JA, among images of the plurality of damages DB included in the second damage image JB, is applied to the laser light LB. Therefore, here, the trefoil aberration pattern that is displayed on the spatial light modulator 7 can be adjusted.

As described above, in the laser adjustment method and the laser processing apparatus 1 according to this embodiment, in the adjustment process (process S79), the trefoil aberration that is applied to the laser light LB is adjusted. In this manner, when suppressing a variation in processing results, the trefoil aberration that is applied to the laser light LB may be adjusted.

Particularly, in the laser adjustment method and the laser processing apparatus 1 according to this embodiment, in the processing process (process S74), the film 112 is irradiated with the laser light LB a plurality of times while varying the trefoil aberration that is applied to the laser light LB, thereby forming a plurality of the damages DB in the film 112. In addition, in the imaging process (S77), the film 112 is imaged to acquire a plurality of the second damage images JB including images of the plurality of damage DB. Then, in the adjustment process (process S79), the aberration that is applied to the laser light LB is adjusted so that the trefoil aberration when forming the damage DB, which is relatively close to the image of the damage DA included in the first damage image JA, among images of the plurality of damages DB included in the second damage image JB, is applied to the laser light LB. Therefore, the aberration can be adjusted so that the damage DB that is shown in the film 112 of the film wafer 110B becomes more reliably close to the damage DA that is shown in the film 112 of the film wafer 110A.

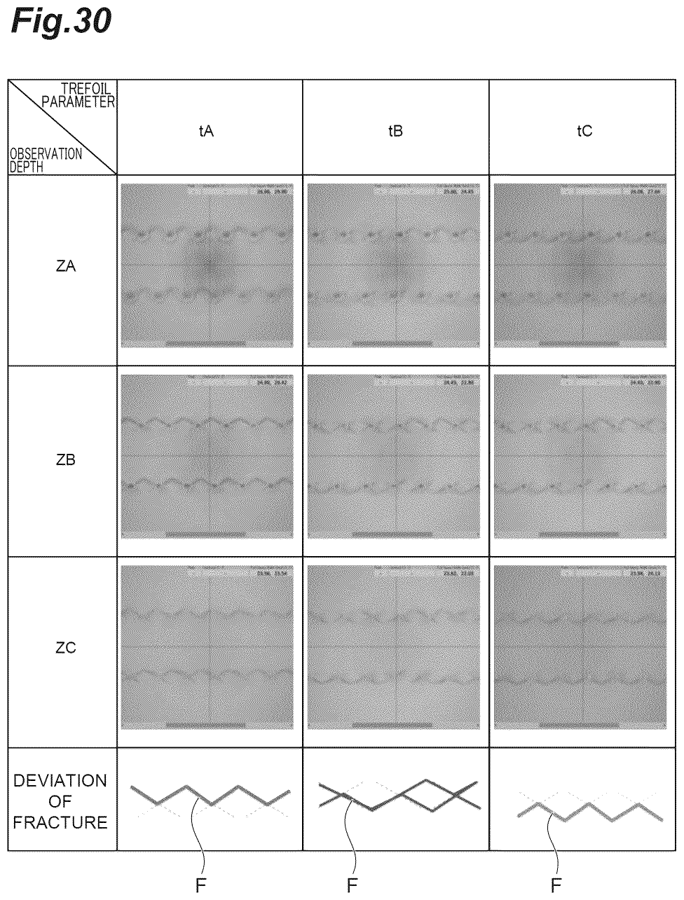

Note that, the following effect can be obtained by using the trefoil aberration when suppressing the machine difference of the laser processing apparatus 1. FIG. 30 is a view illustrating an effect when using the trefoil aberration. A “trefoil parameter” in FIG. 30 is the above-described trefoil aberration intensity, and “tA”, “tB”, and “tC” correspond values specified by α and β in the parameters (t1-α, t2-β). In addition, “observation depth” in FIG. 30 represents a position in the Z-direction where each image is captured in the object 11. As going from ZA toward ZC, a position becomes deeper from an incident surface, and ZB is near the converging point C.

In addition, each image in FIG. 30 is an image that is obtained by imaging the vicinity of the converging point C from a plane (XY plane) parallel to laser light incident surface in the object 11. Further, “deviation of fracture” in FIG. 30 schematically represents a deviation of a fracture extending from the modified region 12 formed by processing with the laser light L to which the trefoil aberration in each off trefoil parameters tA, tB, and tC is applied. In the example illustrated in the drawing, a right and left direction on the paper represents a processing progress direction (X-direction) and a downward direction of the paper is a direction (Y-direction) orthogonal to the processing progress direction. In addition, the “deviation of fracture” represents a deviation with respect to the Y-direction.

As illustrated in FIG. 30, the deviation of the fracture can be controlled by changing the trefoil parameter. In the example illustrated in the drawing, in a case where the trefoil parameter is “tA”, the fracture is in a state of being deviated to one side in the Y-direction, and in a case where the trefoil parameter is “tC”, the fracture is in a state of being deviated to the other side in the Y-direction. On the other hands, in a case where the trefoil parameter is “tB”, no noticeable deviation of the fracture in the Y-direction is observed, and the fracture is in a random state. In this manner, when the trefoil parameter capable of obtaining a random state without deviation of the fracture is set, external appearance quality and breakability of the object 11 after being divided can be improved.

### Modification Example

In the above-described embodiments, an aspect of the present disclosure has been described. Accordingly, the present disclosure is not limited to the above-described aspect, and can be arbitrarily modified.

For example, in the above-described embodiments, description has been given of a case where each aberration is independently adjusted in the respective embodiments as in the first embodiment in which the comma aberration is adjusted, the second embodiment in which the astigmatism is adjusted, the third embodiment in which the spherical aberration is adjusted, and the fourth embodiment in which the trefoil aberration is adjusted. However, actually, in the modulation pattern that is displayed on the spatial light modulator 7, various patterns such as the comma aberration pattern that applies the comma aberration to the laser light L, the astigmatism pattern that applies the astigmatism to the laser light L, the spherical aberration correction pattern that corrects the spherical aberration, and the trefoil aberration pattern that applies the trefoil aberration to the laser light L may overlap each other in some cases. Accordingly, in a case where the laser light L is subjected to the modulation pattern through the spatial light modulator 7, influences due to a plurality of aberrations may also be superposed on the damage D by the leaked light L0.

Therefore, in a case of adjusting the aberration that is applied to the laser light LB so that an image of the damage DA in the apparatus A becomes close to an image of the damage DB in the apparatus B, at least two kinds of the comma aberration, the astigmatism, the spherical aberration, and the trefoil aberration may be compositely adjusted. In other words, elements of the first embodiment, the second embodiment, the third embodiment, and the fourth embodiment can be appropriately combined and implemented.

In addition, as in the above-described embodiments, even in a case of independently adjusting the respective aberrations, an adjustment method can be arbitrarily modified. As an example, in the first embodiment, in the adjustment process (process S20), description has been given of a case where the comma aberration that is applied to the laser light LB is adjusted so that the amount and the direction of the deviation between the position of the image of the modified region 12B and the central position of the image of the damage DB become close to the amount and the direction of the deviation between the position of the image of the modified region 12A and the central position of the image of the damage DA.

However, in the first embodiment, in the adjustment process (process S20), the comma aberration that is applied to the laser light LB may be simply adjusted so that the shape of the damage DB becomes close to the shape of the damage DA on the basis of comparison between the first damage image JA and the second damage image JB. In this case, imaging (process S5) for obtaining the image of the modified region 12A that is the first processing mark and imaging (process S15) for obtaining the image of the modified region 12B that is the second processing mark are not essential.

In addition, in the third embodiment, in the processing process (S54), the film 112 is irradiated with the laser light LB (leaked light LB0 that is a part of the laser light LB) a plurality of times while varying the spherical aberration that is applied to the laser light LB, thereby forming a plurality of the damages DB in the film 112, and in the adjustment process (S59), the aberration that is applied to the laser light LB is adjusted so that the spherical aberration when forming a damage DB, which is relatively close to the damage DA, among the plurality of damages DB is applied to the laser light LB. In this way, the first embodiment or the second embodiment may employ the method in which the plurality of damages DB are formed in advance while changing the amount of aberration, and a damage DB close to the damage DA that is a reference is selected among the plurality of damages DB.

In addition, in the respective embodiments, in a case where the image of the processing marks (modified regions 12A and 12B) is not essential (case where formation of the modified regions 12A and 12B is not essential), it is not also essential to set the first surface 111a of the wafer 111 on a side opposite to the film 112 as an incident surface of the laser light LA or LB, and to set the converging point C of the laser light LA or LB inside the wafer 111.

As an example, a surface of the film 112 on the wafer 111 side may be irradiated with the laser light LA or LB while the laser light LA or LB diffuses from the converging point C by setting a surface of the film 112 on a side opposite to the wafer 111 as an incident surface of the laser light LA or LB, and by forming the converging point C on the laser irradiation unit 3 side (for example, an outer side of the film 112) as compared with at least the surface (surface in which the damage DA or DB is formed) of the film 112 on the wafer 111 side.

In addition, the surface of the film 112 on the wafer 111 side may be irradiated with the laser light LA or LB while the laser light LA or LB converges toward the converging point C by setting the surface of the film 112 on a side opposite to the wafer 111 as an incident surface of the laser light LA or LB, and by forming the converging point C on the wafer 111 side as compared with at least the surface (surface in which the damage DA or DB is formed) of the film 112 on the wafer 111 side.

On the other hand, even in a case where the first surface 111a of the wafer 111 is set as the incident surface of the laser light LA or LB, and the converging point C of the laser light LA or LB is set inside the wafer 111, the converging point C of the laser light LA or LB may be set to a position (for example, a deeper position close to the film 112) different from a position of the converging point C of the laser light L in the Z-direction during actual device processing.

On the other hand, in a case where the first surface 111a of the wafer 111 is set as the incident surface of the laser light LA or LB, the converging point C of the laser light LA or LB may be set to the outside of the wafer 111 with respect to the Z-direction. In this case, for example, the converging point C of the laser light LA or LB can be set to a further outer side of the film 112 beyond the film 112 from the wafer 111.

Furthermore, in the respective embodiments, in the process of performing irradiation with the laser light LA or LB (for example, the processing process), a pulse pitch of the laser light LA or LB may be set to be different from a pulse pitch of the laser light L during actual device processing (for example, may be set to be wider).

### INDUSTRIAL APPLICABILITY

A laser adjustment method and a laser processing apparatus capable of suppressing a variation in processing results are provided.

### REFERENCE SIGNS LIST

1: laser processing apparatus, 2: stage (support unit), 3: laser irradiation unit, 6: control unit (retention unit), 7: spatial light modulator, 8: imaging unit, 12A: modified region (first processing mark), 12B: modified region (second processing mark), 110A: film wafer (first film wafer), 110B: film wafer (second film wafer), 111: wafer (first wafer, second wafer), 112: film (first film, second film), DA: damage (first damage), DB: damage (second damage), IA: first processing image, IB: second processing image, JA: first damage image, JB: second damage image, LA: laser light (first laser light), LB: laser light (second laser light).

1. A laser adjustment method, comprising:
a first preparation process of acquiring an image including an image of a first damage formed in a first film due to irradiation of a first film wafer including a first wafer and the first film provided in the first wafer with first laser light as a first damage image;
a second preparation process of preparing a second film wafer including a second wafer and a second film provided in the second wafer;
a processing process of irradiating the second film wafer with second laser light after the first preparation process and the second preparation process to form a second damage in the second film;
an imaging process of imaging the second film to acquire an image including an image of the second damage as a second damage image after the processing process; and
an adjustment process of adjusting an aberration that is applied to the second laser light so that the image of the second damage included in the second damage image becomes close to the image of the first damage included in the first damage image after the imaging process.

2. The laser adjustment method according to claim 1, further comprising:
a display process of displaying the first damage image and the second damage image after the imaging process,
wherein in the adjustment process, after the display process, the aberration that is applied to the second laser light is adjusted so that the image of the second damage becomes close to the image of the first damage on the basis of a comparison result between the image of the second damage included in the second damage image and the image of the first damage included in the first damage image.

3. The laser adjustment method according to claim 1,
wherein in the adjustment process, a comma aberration that is applied to the second laser light is adjusted.

4. The laser adjustment method according to claim 3,
wherein in the first preparation process, the first wafer is irradiated with the first laser light from a surface side of the first wafer which is opposite to the first film to further acquire an image including an image of a first processing mark formed in the first wafer as a first processing image,
the first damage image includes an image of the first damage formed by leaked light of the first laser light when forming the first processing mark included in the first processing image,
in the processing process, the second wafer is irradiated with the second laser light from a surface side of the second wafer which is opposite to the second film to form a second processing mark in the second wafer and form the second damage in the second film by leaked light of the second laser light,
in the imaging process, the second wafer is imaged to acquire an image including an image of the second processing mark as a second processing image, and
in the adjustment process, the comma aberration that is applied to the second laser light is adjusted so that the amount and a direction of deviation between a position of the image of the second processing mark included in the second processing image and a central position of the image of the second damage included in the second damage image become close to the amount and a direction of deviation between a position of the image of the first processing mark included in the first processing image and a central position of the image of the first damage included in the first damage image.

5. The laser adjustment method according to claim 1,
wherein in the adjustment process, an astigmatism that is applied to the second laser light is adjusted.

6. The laser adjustment method according to claim 5,
wherein in the first preparation process, a first angle that is an angle of the image of the first damage included in the first damage image with respect to a reference direction, and a first ellipticity that is an ellipticity of the image of the first damage are further acquired, and
in the adjustment process, the astigmatism that is applied to the second laser light is adjusted so that a second angle that is an angle of the image of the second damage included in the second damage image with respect to the reference direction and a second ellipticity that is an ellipticity of the image of the second damage become close to the first angle and the first ellipticity.

7. The laser adjustment method according to claim 1,
wherein in the adjustment process, a spherical aberration that is applied to the second laser light is adjusted.

8. The laser adjustment method according to claim 7,
wherein in the processing process, the second film is irradiated with the second laser light a plurality of times while varying the spherical aberration that is applied to the second laser light to form a plurality of the second damages in the second film,
in the imaging process, the second film is imaged to acquire the second damage image including images of a plurality of the second damages, and
in the adjustment process, the aberration that is applied to the second laser light is adjusted so that the spherical aberration when forming a second damage, which is relatively close to the image of the first damage included in the first damage image, among the images of the plurality of second damages included in the second damage image is applied to the second laser light.

9. The laser adjustment method according to claim 1,
wherein in the adjustment process, a trefoil aberration that is applied to the second laser light is adjusted.

10. The laser adjustment method according to claim 9,
wherein in the processing process, the second film is irradiated with the second laser light a plurality of times while varying the trefoil aberration that is applied to the second laser light to form a plurality of the second damages in the second film,
in the imaging process, the second film is imaged to acquire the second damage image including images of the plurality of second damages, and
in the adjustment process, the aberration that is applied to the second laser light is adjusted so that the trefoil aberration when forming a second damage, which is relatively close to the image of the first damage included in the first damage image, among the images of the plurality of second damages included in the second damage image, is applied to the second laser light.

11. The laser adjustment method according to claim 1,
wherein the second laser light is modulated by a modulation pattern displayed in a spatial light modulator, and
in the adjustment process, the modulation pattern is adjusted to adjust the aberration that is applied to the second laser light.

12. A laser processing apparatus, comprising:
a support unit configured to support an object;
a laser irradiation unit configured to irradiate the object supported by the support unit with laser light;
an imaging unit configured to image the object;
a retention unit configured to retain an image; and
a control unit configured to control at least the laser irradiation unit and the imaging unit,
wherein the laser irradiation unit includes a spatial light modulator configured to modulate the laser light in correspondence with a modulation pattern and emit the laser light,
the retention unit retains an image including an image of a first damage formed in a first film due to irradiation of a first film wafer including a first wafer and the first film provided in the first wafer with first laser light as a first damage image, and
the control unit executes,
a processing process of irradiating a second film wafer with second laser light according to control by the laser irradiation unit in a state in which as the object, the second film wafer including a second wafer and a second film provided in the second wafer is supported by the support unit,
an imaging process of imaging the second film according to control by the imaging unit after the processing process to acquire an image including an image of a second damage formed in the second film due to irradiation with the second laser light as a second damage image, and
an adjustment process of adjusting an aberration that is applied to the second laser light by adjusting the modulation pattern so that the image of the second damage included in the second damage image becomes close to the image of the first damage included in the first damage image.
